(19) United States
(12) Patent Application Publication
(10) Pub. No.: US 2024/0304267 A1
(43) Pub. Date: Sep. 12, 2024

(54) ARTIFICIAL INTELLIGENCE PROCESSING DEVICE AND TRAINING INFERENCE METHOD FOR ARTIFICIAL INTELLIGENCE PROCESSING DEVICE

(71) Applicant: Nuvoton Technology Corporation Japan, Kyoto (JP)

(72) Inventors: Ryutaro YASUHARA, Hyogo (JP); Satoru FUJII, Osaka (JP); Shunsaku MURAOKA, Osaka (JP)

(21) Appl. No.: 18/670,281

(22) Filed: May 21, 2024

Related U.S. Application Data
(63) Continuation of application No. PCT/JP2022/044141, filed on Nov. 30, 2022.

(30) Foreign Application Priority Data
Dec. 13, 2021 (JP) 2021-201499

(51) Int. Cl. G11C 27/00; G06F 7/50; G06F 7/523; G06N 3/092; H10B 63/00

(52) U.S. Cl. CPC G11C 27/005; G06F 7/50; G06F 7/523; G06N 3/092; H10B 63/82

(57) ABSTRACT

An artificial intelligence processing device includes: a first variable-resistance nonvolatile storage element and a second variable-resistance nonvolatile storage element having different properties and provided on a single substrate. When successive applications of a voltage pulse with a same polarity and a same voltage are made, a proportion of an amount of change in conductance caused by a second application of the voltage pulse relative to an amount of change in conductance caused by a first application of the voltage pulse in the first variable-resistance nonvolatile storage element is less than a proportion of an amount of change in conductance caused by a second application of the voltage pulse relative to an amount of change in conductance caused by a first application of the voltage pulse in the second variable-resistance nonvolatile storage element.

### CROSS REFERENCE TO RELATED APPLICATIONS

This is a continuation application of PCT International Application No. PCT/JP2022/044141 filed on Nov. 30, 2022, designating the United States of America, which is based on and claims priority of Japanese Patent Application No. 2021-201499 filed on Dec. 13, 2021. The entire disclosures of the above-identified applications, including the specifications, drawings and claims are incorporated herein by reference in their entirety.

### FIELD

The present disclosure relates to an artificial intelligence processing device and a training inference method therefor, and in particular to an artificial intelligence processing device that includes variable-resistance nonvolatile storage elements each having a resistance that varies according to a given electrical signal.

### BACKGROUND

Along with development of information communication technology, the arrival of Internet of Things (IoT) technology with which everything is connected to the internet has been attracting attention. With the IoT technology, performance of various electronic devices is expected to be improved by the devices being connected to the internet, but nevertheless, as technology for achieving further improvement in performance, research and development of artificial intelligence (AI) technology that allows electronic devices to train themselves and make determinations have been actively conducted in recent years.

In the AI technology, neural network technology in which human brain information processing is technologically imitated has been used, and research and development of semiconductor integrated circuits that perform neural network computation at high speed with low power consumption have been actively conducted.

Patent Literature (PTL) 1 discloses a conventional neural network computing circuit. A neural network includes basic elements referred to as neurons (that may also be referred to as perceptrons) having different connection weight coefficients and connected to inputs by joints referred to as synapses, and can perform advanced computing processing such as image recognition and speech recognition by the neurons being connected to one another. Each neuron performs a multiply-accumulate operation to obtain a sum total of products resulting from multiplying inputs by its connection weight coefficient. A multiply-accumulate operation circuit includes a memory circuit and a register circuit that store therein inputs and connection weight coefficients, a multiplication circuit that multiplies inputs by connection weight coefficients, an accumulator circuit that accumulates results of multiplications, and a control circuit that controls operation of such circuit blocks. All the circuit blocks are configured of digital circuits.

PTL 2 discloses another example of a conventional neural network computing circuit. A neural network computing circuit is configured using a variable resistance nonvolatile memory having settable multi-level analog resistance or settable conductance that is a reciprocal of the resistance (hereinafter, simply referred to as “conductance”). The neural network computing circuit stores conductance corresponding to a connection weight coefficient in a nonvolatile memory element, applies a voltage having a value corresponding to an input to the nonvolatile memory element, and utilizes a value of an analog current flowing through the nonvolatile memory element at this time. A multiply-accumulate operation performed in a neuron is performed by storing, as conductance, connection weight coefficients into nonvolatile memory elements, applying voltages having values corresponding to inputs to the nonvolatile memory elements, and obtaining, as a result of the multiply-accumulate operation, an analog current value resulting from adding up values of currents flowing through the nonvolatile memory elements. Here, as a write method for writing conductance to nonvolatile memories, conductance to be written to each nonvolatile memory is calculated from a connection weight coefficient derived in advance, and the conductance is written to the nonvolatile memory.

Non Patent Literature (NPL) 1 discloses yet another example of a conventional neural network computing circuit. Also in this literature, a neural network computing circuit is configured using a variable resistance nonvolatile memory having settable conductance, conductance corresponding to a connection weight coefficient is stored in a nonvolatile memory element, an analogue voltage having a value corresponding to an input is applied to the nonvolatile memory element, and a value of an analog current flowing through the nonvolatile memory element at this time is utilized, which is the same as Patent Literature 2. Here, as a write method used when writing conductance to the nonvolatile memory, an amount of change between conductance before writing and conductance set after writing is derived first, and writing according to the amount of change in conductance can be performed on the nonvolatile memory element.

Thus, in the example of the neural network computing circuit as shown in PTL 2, write operation is performed normally based on conductance itself that is to be written to a nonvolatile memory, whereas in the neural network computing circuit as shown in NPL 1, write operation is performed normally based on an amount of change in conductance before and after writing conductance to a nonvolatile memory, which is a difference. The neural network computing circuits disclosed in PTL 2 and NPL 1, in which nonvolatile memory elements are used, can both reduce power consumption as compared with the above-stated neural network computing circuit that includes digital circuits, and process development, device development, and circuit development for variable-resistance nonvolatile memories having settable conductance have been actively conducted in recent years.

### CITATION LIST

### Patent Literature

PTL 1: Japanese Unexamined Patent Application Publication No. 2001-188767
PTL 2: International Publication No. WO 2019/049741

### Non Patent Literature

NPL 1: M. Prezioso, et al., “Training and operation of an integrated neuromorphic network based on metal-oxide memristors,” Nature, no. 521, pp. 61-64, 2015

### SUMMARY

### Technical Problem

However, the above-stated conventional neural network computing circuits have problems as follows.

Specifically, a neural network computing circuit in which write operation is performed based on the very conductance that is written to a nonvolatile memory performs writing using the very conductance derived in advance, and thus can accurately write conductance to a nonvolatile memory element. Hence, it is suitable for an “artificial intelligence processing device for inference” that performs only a multiply-accumulate operation mainly using a neural network after product shipment (that is, after shipping an artificial intelligence processing device that includes a neural network computing circuit, for instance). However, normally, a neural network based on a premise that processing is performed using software updates a connection weight coefficient, or stated differently, is trained based on an amount of change in the connection weight coefficient. Thus, an “artificial intelligence processing device for training” that frequently updates conductance after product shipment has a problem that training is not efficiently performed if a neural network computing circuit is used in which write operation is performed based on conductance itself.

FIG. 1A illustrates processes in training in a neural network computing circuit, in which write operation is performed based on conductance itself. In the processes, inference is performed using connection weight coefficients of nonvolatile memory elements (S10), a difference between the result of the inference and a teacher label is checked (S11), an amount of change in a connection weight coefficient when the connection weight coefficient is updated is calculated for each of the nonvolatile memory elements (S12), a current connection weight coefficient is read out from each of the nonvolatile memory elements (S13), an updated connection weight coefficient is calculated for each of the nonvolatile memory elements, based on the connection weight coefficient read out (S14), and the calculated connection weight coefficient is written to each of the nonvolatile memory elements (S15). Thus, writing the connection weight coefficients themselves requires six steps.

FIG. 1B illustrates processes in training in a neural network computing circuit, in which write operation is performed based on an amount of change before and after conductance is written. In the processes, inference is performed using connection weight coefficients of nonvolatile memory elements (S10), a difference between the result of the inference and a teacher label is checked (S11), an amount of change in a connection weight coefficient when the connection weight coefficient is updated is calculated for each of the nonvolatile memory elements (S12), and the connection weight coefficient is updated for each of the nonvolatile memory elements by changing the current connection weight coefficient by the calculated amount of change in connection weight coefficient (S20). Thus, writing an amount of change in a connection weight coefficient involves just four steps. It can be seen that the training processes in FIG. 1B can be performed through the same processes as those performed when neural network computation is performed on a software basis, and has less procedure than the training processes illustrated in FIG. 1A.

The neural network computing circuit in which write operation is performed based on an amount of change made before and after writing conductance performs a write operation based on the amount of change, and thus can update the conductance in the training processes in FIG. 1B, and is suitable for an “artificial intelligence processing device for training” that frequently updates conductance after product shipment. However, when “initial setting” before product shipment is made, the neural network computing circuit implemented with the training processes illustrated in FIG. 1B cannot perform writing using conductance itself derived in advance, and needs to change the conductance to a value derived in advance by successively applying a voltage pulse multiple times. At that time, write properties vary, and initial setting cannot be made highly efficiently or accurately, which is a problem.

The present disclosure has been achieved in light of the above problems, and is to provide an artificial intelligence processing device and a training inference method therefor using variable-resistance nonvolatile storage elements that can achieve both of setting connection weight coefficients (initial setting) with high accuracy at the time of product shipment, for instance, and updating connection weight coefficients (training) with high efficiency after product shipment, for instance.

### Solution to Problem

An artificial intelligence processing device according to an aspect of the present disclosure includes: a substrate; and a multiply-accumulate operation circuit that is provided on the substrate, and performs a multiply-accumulate operation. The multiply-accumulate operation circuit includes: a first variable-resistance nonvolatile storage element and a second variable-resistance nonvolatile storage element that hold, as conductance, a connection weight coefficient for use in calculating a product in the multiply-accumulate operation, the first variable-resistance nonvolatile storage element and the second variable-resistance nonvolatile storage element having different properties, and when successive applications of a voltage pulse with a same polarity and a same voltage are made, a proportion of an amount of change in the conductance caused by a second application of the voltage pulse relative to an amount of change in the conductance caused by a first application of the voltage pulse in the first variable-resistance nonvolatile storage element is less than a proportion of an amount of change in the conductance caused by a second application of the voltage pulse relative to an amount of change in the conductance caused by a first application of the voltage pulse in the second variable-resistance nonvolatile storage element.

A training inference method for the artificial intelligence processing device according to an aspect of the present disclosure includes: determining, in a case where the connection weight coefficient is to be changed, whether the case is a first case in which the connection weight coefficient is changed for initial setting or a second case in which the connection weight coefficient is changed in training; changing the conductance of the first variable-resistance nonvolatile storage element when the case is determined to be the first case as a result of the determining; changing the conductance of the second variable-resistance nonvolatile storage element when the case is determined to be the second case as a result of the determining; and making inference by using, as one product in the multiply-accumulate operation, a sum total of a current flowing through the first variable-resistance nonvolatile storage element and a current flowing through the second variable-resistance nonvolatile storage element, the sum total being output by the multiply-accumulate operation circuit.

### Advantageous Effects

According to the artificial intelligence processing device that includes variable-resistance nonvolatile storage elements and the training inference method therefor according to the present disclosure, both of setting connection weight coefficients (initial setting) with high efficiency and accuracy at the time of product shipment, for instance, and updating connection weight coefficients (training) with high efficiency after product shipment, for instance, can be achieved.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1A illustrates processes in training in a neural network computing circuit, in which write operation is performed based on conductance itself.

FIG. 1B illustrates processes in training in a neural network computing circuit, in which write operation is performed based on an amount of change before and after conductance is written.

FIG. 2 is a cross-sectional schematic diagram illustrating a variable-resistance nonvolatile storage element having conductance that substantially reaches set conductance by a single application of a voltage pulse, according to an embodiment.

FIG. 3 is a cross-sectional schematic diagram illustrating a variable-resistance nonvolatile storage element having conductance that gradually changes by successive applications of a voltage pulse with the same polarity and the same voltage, according to the embodiment.

FIG. 4 illustrates changes in conductance of the variable-resistance nonvolatile storage element having conductance that substantially reaches the set conductance by a single application of a voltage pulse, when the resistance is varied by successive applications of a voltage pulse with the same polarity and the same voltage, according to the embodiment.

FIG. 5 illustrates changes in conductance of the variable-resistance nonvolatile storage element having conductance that gradually changes by successive applications of a voltage pulse with the same polarity and the same voltage, when the resistance is varied by successive applications of a voltage pulse with the same polarity and the same voltage, according to the embodiment.

FIG. 6A is a circuit diagram of a memory cell according to a conventional technique.

FIG. 6B is a cross sectional view of the memory cell according to the conventional technique.

FIG. 7A is a circuit diagram of a memory cell according to an embodiment.

FIG. 7B is a cross sectional view illustrating an example of the memory cell according to the embodiment.

FIG. 7C is a cross sectional view illustrating another example of the memory cell according to the embodiment, which is different from the example illustrated in FIG. 7B.

FIG. 8A is a circuit diagram of a memory cell according to another embodiment.

FIG. 8B illustrates an example of a cross sectional view of a memory cell of an artificial intelligence (AI) processing device that includes a first variable-resistance nonvolatile storage element illustrated in FIG. 8A.

FIG. 8C illustrates an example of a cross sectional view of a memory cell of the AI processing device that includes a second variable-resistance nonvolatile storage element illustrated in FIG. 8A.

FIG. 9A is a block diagram illustrating a model of an AI processing device according to an example.

FIG. 9B illustrates functions of a neuron illustrated in FIG. 9A.

FIG. 10A illustrates an example of a circuit that implements neurons illustrated in FIG. 9B.

FIG. 10B illustrates an example of another circuit that implements neurons illustrated in FIG. 9B.

FIG. 11 is a block diagram illustrating the entire configuration of an AI processing device that includes neurons illustrated in FIG. 10A.

FIG. 12A illustrates examples of applied voltages via word line WL, bit lines BL1 and BL2, and source line SL, in writing to and reading out from a memory cell illustrated in FIG. 10A.

FIG. 12B illustrates examples of applied voltages via word lines WL1 and WL2, bit line BL, and source line SL, in writing to and reading out from a memory cell illustrated in FIG. 10B.

FIG. 13 is a flowchart illustrating an example of operation of a control circuit illustrated in FIG. 11.

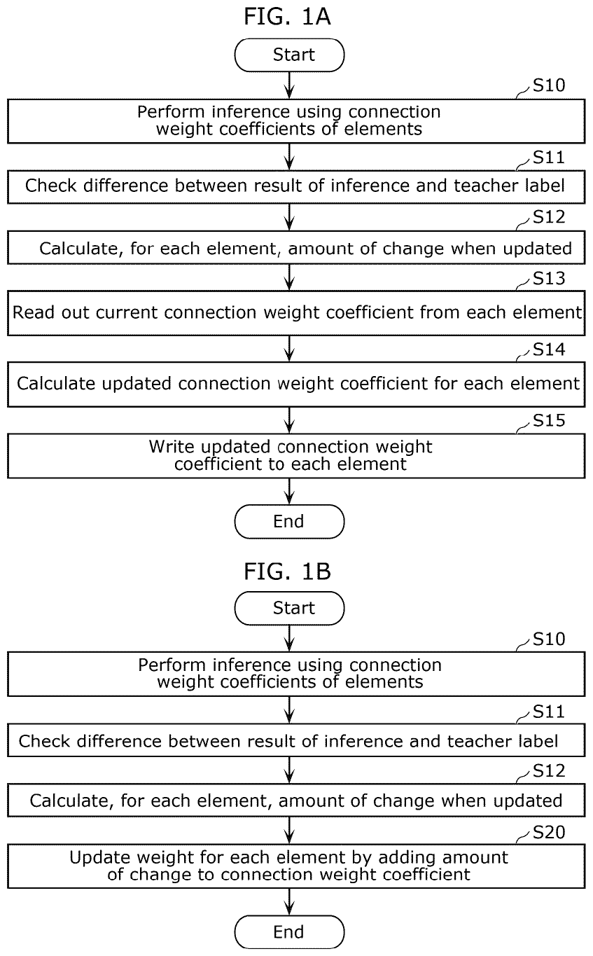

### DESCRIPTION OF EMBODIMENTS

In the following, embodiments according to the present disclosure are to be explained with reference to the drawings. Note that the embodiments explained below each show a specific example. The numerical values, shapes, materials, elements, the arrangement and connection of the elements, steps, and the processing order of the steps, for instance, shown in the following embodiments are mere examples, and therefore are not intended to limit the scope of the present disclosure. The present disclosure is defined only by the claims.

Therefore, among the elements in the following embodiments, elements not recited in any of the independent claims defining the broadest concept of the present disclosure are not necessarily essential to address the problems mentioned in the present disclosure, but are explained as optional elements included in embodiments that may be adopted.

The inventors of the present disclosure have found the following, as a result of diligent examinations in order to enhance operation efficiency of setting connection weight coefficients (initial setting) with high accuracy at the time of product shipment, for instance, and updating connection weight coefficients (training) with high efficiency after product shipment, for instance, in an artificial intelligence processing device that includes variable-resistance nonvolatile storage elements.

The inventors of the present disclosure have found that an artificial intelligence processing device that includes variable-resistance nonvolatile storage elements has a configuration in which the variable-resistance nonvolatile storage elements of two types having different properties are both provided on a single substrate, and through successive applications of a voltage pulse with the same polarity and the same voltage, conductance of one of the nonvolatile storage elements gradually changes, and conductance of the other nonvolatile storage element greatly changes due to the first application of a voltage pulse and slightly changes due to the second and subsequent applications of the voltage pulse. The inventors have found that owing to this configuration, operation efficiency for both of setting connection weight coefficients (initial setting) with high accuracy at the time of product shipment, for instance, and updating connection weight coefficients (training) with high efficiency after product shipment, for instance, in an artificial intelligence processing device that includes variable-resistance nonvolatile storage elements can be enhanced, which has conventionally been a problem.

Details of the findings are to be explained as appropriate together with embodiments in the following.

### Embodiment

### [Configurations of Variable-Resistance Nonvolatile Storage Elements]

First, examples of configurations of two types of variable-resistance nonvolatile storage elements according to an embodiment are to be explained.

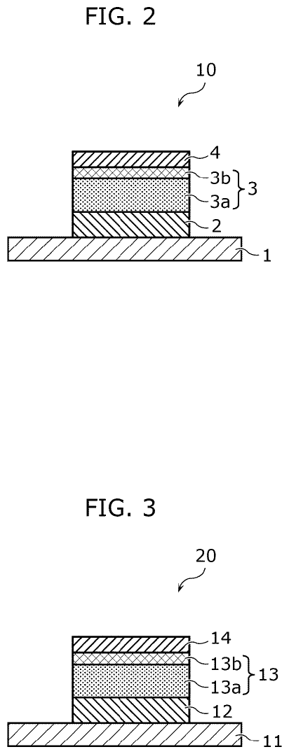

FIG. 2 is a schematic diagram illustrating an example of a configuration of first variable-resistance nonvolatile storage element 10 according to the embodiment. First variable-resistance nonvolatile storage element 10 is a variable-resistance nonvolatile storage element suitable for setting connection weight coefficients (initial setting) with high accuracy at the time of product shipment, for instance.

As illustrated in FIG. 2, first variable-resistance nonvolatile storage element 10 includes substrate 1, first electrode 2 provided above substrate 1, variable resistance layer 3 provided, as a metal oxide layer, above first electrode 2, and second electrode 4 provided above variable resistance layer 3. First electrode 2 and second electrode 4 are electrically connected to variable resistance layer 3. Specifically, first variable-resistance nonvolatile storage element 10 includes first electrode 2, second electrode 4, and variable resistance layer 3 provided between first electrode 2 and second electrode 4.

Note that first electrode 2 may have a size same as the size of second electrode 4, and first electrode 2, second electrode 4, and variable resistance layer 3 may be provided upside down or may be provided laterally.

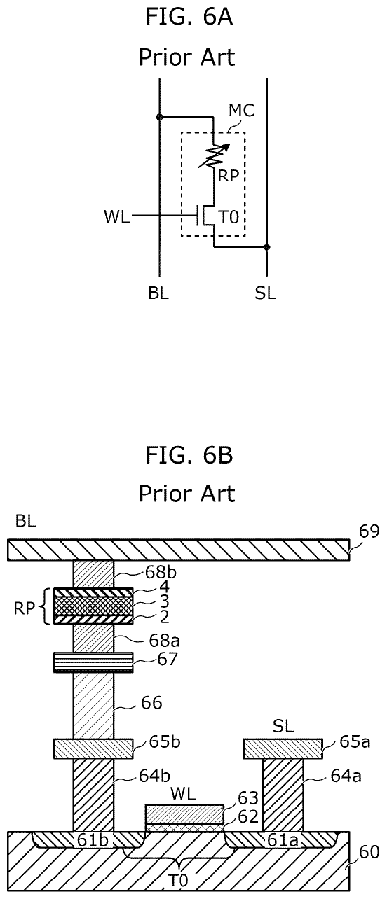

Substrate 1 is configured of a silicon substrate on which circuit elements such as a transistor, for example, are provided. At least one of first electrode 2 or second electrode 4 includes a material out of noble metals such as, for example, Au (gold), Pt (platinum), Ir (iridium), Pd (palladium), and Ru (ruthenium). For example, second electrode 4 in contact with second tantalum oxide layer 3b includes a noble metal, and first electrode 2 includes a noble metal or a non-noble metal. With such features of the electrodes, first variable-resistance nonvolatile storage element 10 has variable resistance properties illustrated in FIG. 4 explained later.

Variable resistance layer 3 has a resistance (or stated differently, conductance) that varies according to a voltage pulse applied between first electrode 2 and second electrode 4. Variable resistance layer 3 includes a metal oxide, and includes a stack of first tantalum oxide layer 3a and second tantalum oxide layer 3b. Here, an oxygen content of second tantalum oxide layer 3b is higher than an oxygen content of first tantalum oxide layer 3a.

When a composition of first tantalum oxide layer 3a is TaOx, 0<x<2.5 may be satisfied and furthermore, when a composition of second tantalum oxide layer 3b is TaOy, x<y may be satisfied.

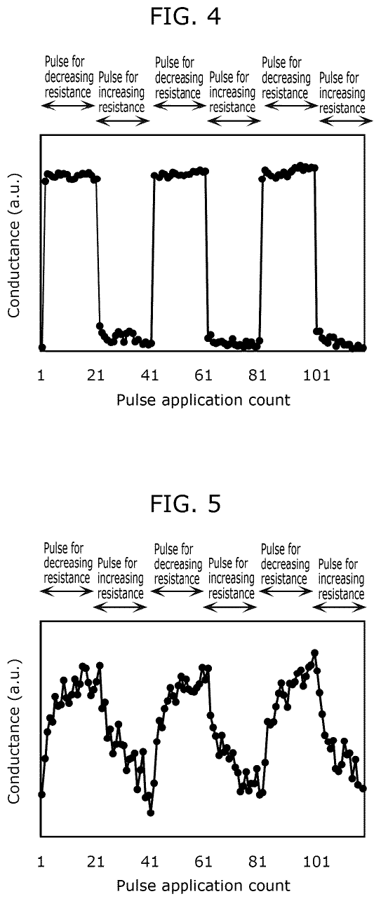

FIG. 3 is a schematic diagram illustrating an example of a configuration of second variable-resistance nonvolatile storage element 20 according to the embodiment. Second variable-resistance nonvolatile storage element 20 is a variable-resistance nonvolatile storage element suitable for updating connection weight coefficients (training) with high efficiency at the time of product shipment, for instance.

As illustrated in FIG. 3, second variable-resistance nonvolatile storage element 20 includes substrate 11, first electrode 12 provided above substrate 11, variable resistance layer 13 provided, as a metal oxide layer, above first electrode 12, and second electrode 14 provided above variable resistance layer 13, similarly to first variable-resistance nonvolatile storage element 10. First electrode 12 and second electrode 14 are electrically connected to variable resistance layer 13. Specifically, second variable-resistance nonvolatile storage element 20 includes first electrode 12, second electrode 14, and variable resistance layer 13 provided between first electrode 12 and second electrode 14.

Note that first electrode 12 may have a size same as the size of second electrode 14, and first electrode 12, second electrode 14, and variable resistance layer 13 may be provided upside down or may be provided laterally.

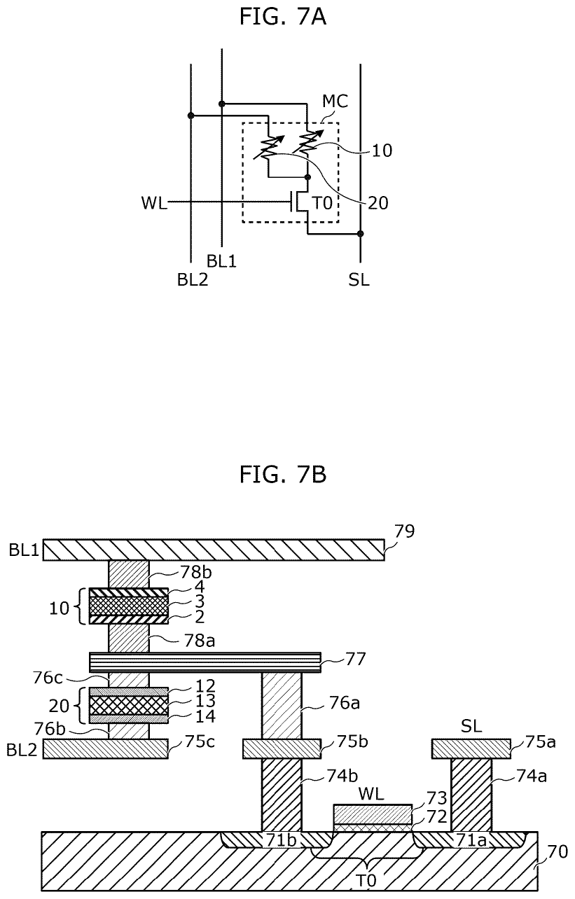

Substrate 11 is configured of a silicon substrate on which circuit elements such as a transistor, for example, are provided. At least one of first electrode 12 or second electrode 14 includes a material out of non-noble metals such as, for example, TiN (titanium nitride) and TaN (tantalum nitride). For example, second electrode 14 in contact with second tantalum oxide layer 3b includes a non-noble metal, and first electrode 12 includes a noble metal or a non-noble metal. With such features of the electrodes, second variable-resistance nonvolatile storage element 20 has variable resistance properties illustrated in FIG. 5 explained later.

Variable resistance layer 13 has a resistance (or stated differently, conductance) that varies according to a voltage pulse applied between first electrode 12 and second electrode 14. Variable resistance layer 13 includes a metal oxide, and includes a stack of first tantalum oxide layer 13a and second tantalum oxide layer 13b. Here, an oxygen content of second tantalum oxide layer 13b is higher than an oxygen content of first tantalum oxide layer 13a.

When a composition of first tantalum oxide layer 13a is TaOx, 0<x<2.5 may be satisfied and furthermore, when a composition of second tantalum oxide layer 13b is TaOy, x<y may be satisfied.

### [Method for Manufacturing Variable-Resistance Nonvolatile Storage Elements]

Next, an example of a method for manufacturing first variable-resistance nonvolatile storage element 10 and second variable-resistance nonvolatile storage element 20 is to be explained using the case of a method for manufacturing first variable-resistance nonvolatile storage element 10.

First, first electrode 2 is formed on substrate 1 by sputtering. After that, a tantalum oxide layer is formed on first electrode 2 by so-called reactive sputtering in which a Ta target is sputtered in an argon gas and an oxygen gas. Here, an oxygen content in the tantalum oxide layer can be readily adjusted by changing a flow rate ratio of the oxygen gas to the argon gas. Note that the substrate temperature can be set to a room temperature without particularly heating substrate 1.

Next, the outermost surface of the tantalum oxide layer formed in the above manner is oxidized to modify the property of the outermost surface. Alternatively, a layer having a higher oxygen content is formed by sputtering, using a tantalum oxide (for example, Ta2O5) target having a high oxygen content. Accordingly, on a surface of the tantalum oxide layer formed in advance, a region (a second region) having an oxygen content higher than a region (a first region) of the tantalum oxide layer that is not oxidized is formed.

The first region and the second region correspond to first tantalum oxide layer 3a and second tantalum oxide layer 3b, respectively, and first tantalum oxide layer 3a and second tantalum oxide layer 3b formed in this manner constitute variable resistance layer 3.

Next, second electrode 4 is formed by sputtering, on variable resistance layer 3 formed in the above manner.

Finally, in order to form first variable-resistance nonvolatile storage element 10, using a desired mask, first electrode 2, oxygen-deficient first tantalum oxide layer 3a, second tantalum oxide layer 3b, and second electrode 4 are patterned to form first variable-resistance nonvolatile storage element 10 in which variable resistance layer 3 is provided between first electrode 2 and second electrode 4.

Note that in forming first variable-resistance nonvolatile storage element 10, the same mask is used in this process to collectively pattern the electrodes and layers, but nevertheless, the electrodes and layers may be individually patterned in each process.

Note that the sizes and the shapes of first electrode 2, second electrode 4, and variable resistance layer 3 may be adjusted by using a photomask and photolithography. In the present embodiment, the sizes of second electrode 4 and variable resistance layer 3 are 0.1 μm×0.1 μm (the area of 0.01 μm2) and the size of a portion in which first electrode 2 and variable resistance layer 3 are in contact is 0.1 μm×0.1 μm (the area of 0.01 μm2), but the sizes and shapes are not limited to those and may be appropriately changed by layout design.

Note that a basic flow of the manufacturing method for second variable-resistance nonvolatile storage element 20 is similar to that for first variable-resistance nonvolatile storage element 10, except for a difference in specific material of first electrode 12 or second electrode 14.

### [Operation Manner of Variable-Resistance Nonvolatile Storage Element and Resistance Varying Property]

Next, operation of first variable-resistance nonvolatile storage element 10 and second variable-resistance nonvolatile storage element 20 that are obtained through the above manufacturing method is to be explained.

In the following, the case where the resistance of variable resistance layer 3 has a predetermined large value (300 kΩ, for example) is referred to as a high resistance state and similarly, the case where the resistance of variable resistance layer 3 has a predetermined small value (12 kΩ, for example) is referred to as a low resistance state. Furthermore, the conductance of first variable resistance layer 10 and the conductance of second variable-resistance nonvolatile storage element 20 are assumed to vary between the high and low resistance states by successive applications of a voltage pulse with the same polarity and the same voltage.

Moreover, in the following, a process in which the conductance of variable resistance layer 3 increases and variable resistance layer 3 changes from the high resistance state to the low resistance state by a write voltage pulse having a negative polarity being applied between first electrode 2 and second electrode 4 of first variable-resistance nonvolatile storage element 10 or first electrode 12 and second electrode 14 of second variable-resistance nonvolatile storage element 20 is referred to as a decrease in resistance (or alternatively, referred to as “setting”), whereas a process in which the conductance of variable resistance layer 3 decreases and variable resistance layer 3 changes from the low resistance state to the high resistance state by a write voltage pulse having a positive polarity being applied between first electrode 2 (12) and second electrode 4 (14) is referred to as an increase in resistance (or alternatively, referred to as “resetting”). Such a decrease and an increase in resistance of the variable-resistance nonvolatile storage elements are referred to as “writing” conductance or a resistance.

By repeating such writing, first variable-resistance nonvolatile storage element 10 and second variable-resistance nonvolatile storage element 20 operate as nonvolatile storage elements.

Here, an initial process is to be explained. In the present embodiment, normally an initial process is executed just once before the writing is performed for the first time. The initial process is a preparation process for achieving a stable resistance varying operation in decreasing and increasing resistance afterwards, and is referred to as “break” or “forming”.

Normally, each of first variable-resistance nonvolatile storage element 10 and second variable-resistance nonvolatile storage element 20 immediately after being manufactured has an initial resistance higher than the resistance in the high resistance state achieved when the resistance normally varies, and the resistance does not vary even if a voltage pulse for decreasing the resistance or a voltage pulse for increasing the resistance, which are applied during normal operation, is applied in such a state.

In view of this, an initial voltage pulse is applied between first electrode 2 and second electrode 4 in the initial process.

After that, the conductance of first variable-resistance nonvolatile storage element 10 and the conductance of second variable-resistance nonvolatile storage element 20 are changed between the high resistance state and the low resistance state by successively applying a voltage pulse with the same polarity and the same voltage in increasing or decreasing the resistance.

Thus, the initial process is a process performed on first variable-resistance nonvolatile storage element 10 and second variable-resistance nonvolatile storage element 20 in the initial state when a voltage is not yet applied after first variable-resistance nonvolatile storage element 10 and second variable-resistance nonvolatile storage element 20 are manufactured.

A local region, which is called a filament, having a higher oxygen deficiency than the oxygen deficiency of a portion therearound is formed in variable resistance layer 3, by undergoing the initial process explained above.

Note that in the present embodiment, a filament is formed by undergoing the initial process, yet a filament does not necessarily need to be formed through the initial process, but instead, an oxide layer having an oxygen deficiency sufficiently higher than 0% may be provided when the variable-resistance nonvolatile storage element is formed.

Next, unique properties of first variable-resistance nonvolatile storage element 10 according to the present embodiment are to be explained. FIG. 4 illustrates resistance varying properties when the conductance of first variable-resistance nonvolatile storage element 10 according to the present embodiment is changed to the high resistance state or to the low resistance state by successively applying a voltage pulse with the same polarity and the same voltage to first variable-resistance nonvolatile storage element 10. The horizontal axis shows the number of times a voltage pulse is applied, whereas the vertical axis shows conductance. As illustrated in FIG. 4, when a voltage pulse with the same polarity and the same voltage is successively applied to first variable-resistance nonvolatile storage element 10 to decrease the resistance, as shown by the plotted black dots on the upper side of the rectangular waves in FIG. 4, the first application of the voltage pulse causes a great change in conductance and increases the conductance from the high resistance state to the state close to the low resistance state. After that, the second and third applications of the voltage pulse are successively made, but merely cause a very small change in conductance as compared with the change in conductance caused by the first application of the voltage pulse. Similarly, when a voltage pulse with the same polarity and the same voltage is successively applied to first variable-resistance nonvolatile storage element 10 to increase the resistance, as shown by the plotted black dots on the lower side of the rectangular waves in FIG. 4, the first application of the voltage pulse causes a great change in conductance and decreases the conductance from the low resistance state to the state close to the high resistance state. After that, the second and third applications of the voltage pulse are successively made, but merely cause a very small change in conductance as compared with the change in conductance caused by the first application of the voltage pulse.

For first variable-resistance nonvolatile storage element 10 that exhibits such resistance varying properties, the conductance itself (or stated differently, multi-level analog resistance) in the low resistance state can be adjusted by a current limiting circuit connected to the element. Thus, first variable-resistance nonvolatile storage element 10 has properties with which the conductance greatly changes due to the first application of the voltage pulse out of successive applications of the voltage pulse, and shows a small change caused by the subsequent applications of the voltage pulse. Accordingly, first variable-resistance nonvolatile storage element 10 can be considered to be a variable-resistance nonvolatile storage element suitable for setting connection weight coefficients (initial setting) with high accuracy at the time of product shipment, for instance. Thus, by using first variable-resistance nonvolatile storage element 10 and the current limiting circuit, in an AI processing device that includes variable-resistance nonvolatile storage elements, conductance setting values of elements can be obtained in advance and written in the elements at least one of when firmware is updated before or after product shipment, when learning models are updated, when regular maintenance is performed, or when connection weight coefficients are insufficiently updated by changing the conductance of second variable-resistance nonvolatile storage element 20.

Next, unique properties of second variable-resistance nonvolatile storage element 20 according to the present embodiment are to be explained. FIG. 5 illustrates resistance varying properties when the conductance of second variable-resistance nonvolatile storage element 20 according to the present embodiment is changed to the high resistance state or to the low resistance state by successively applying a voltage pulse with the same polarity and the same voltage to second variable-resistance nonvolatile storage element 20. The horizontal axis shows the number of times a voltage pulse is applied, whereas the vertical axis shows conductance.

As illustrated in FIG. 5, when a voltage pulse with the same polarity and the same voltage are successively applied to second variable-resistance nonvolatile storage element 20 to decrease the resistance, as shown by the plotted black dots on the rising waves in FIG. 5, a rate of change in conductance caused by the first application of the voltage pulse is smaller than a rate of change in conductance caused by the first application of the voltage pulse to first variable-resistance nonvolatile storage element 10. After that, when the second and third applications of the pulse are successively made, a change in conductance to decrease the resistance continuously occurs. Similarly, when a voltage pulse with the same polarity and the same voltage are successively applied to second variable-resistance nonvolatile storage element 20 to decrease the resistance, as shown by the plotted black dots on the falling waves in FIG. 5, a rate of change in conductance caused by the first application of the voltage pulse is smaller than a rate of change in conductance caused by the first application of the voltage pulse to first variable-resistance nonvolatile storage element 10. After that, when the second and third applications of the pulse are successively made, a change in conductance to increase the resistance continuously occurs.

In second variable-resistance nonvolatile storage element 20 exhibiting such resistance varying properties, irrespective of the conductance before a pulse being applied, a certain amount of an increase in conductance (a decrease in resistance) or a decrease in conductance (an increase in resistance) can be made by applying a voltage pulse with a polarity for decreasing the resistance or a voltage pulse with a polarity for increasing the resistance. Thus, second variable-resistance nonvolatile storage element 20 has properties with which conductance gradually changes due to successive applications of the voltage pulse. Accordingly, second variable-resistance nonvolatile storage element 20 can be considered to be a variable-resistance nonvolatile storage element suitable for updating connection weight coefficients (training) with high efficiency after product shipment, for instance. Thus, by using second variable-resistance nonvolatile storage element 20, in an AI processing device that includes variable-resistance nonvolatile storage elements, when connection weight coefficients for training after product shipment are updated, writing for increasing or decreasing conductance by a certain amount can be directly made to the elements. If a voltage pulse with the same polarity and the same voltage is successively applied multiple times, a proportion of an amount of change in conductance caused by the second application of the voltage pulse relative to an amount of change in conductance caused by the first application of the voltage pulse in second variable-resistance nonvolatile storage element 20 is greater than a proportion of an amount of change in conductance caused by the second application of the voltage pulse relative to an amount of change caused by the first application of the voltage pulse in first variable-resistance nonvolatile storage element 10.

As explained above, a comparison between first variable-resistance nonvolatile storage element 10 that substantially reaches set conductance by a single application of a voltage pulse and second variable-resistance nonvolatile storage element 20 having conductance that gradually changes by successive applications of a voltage pulse with the same polarity and the same voltage shows that first variable-resistance nonvolatile storage element 10 having conductance that can be set by a single application of a voltage pulse is considered to more firmly maintain a specific resistance state, and thus is considered to have a high retention property after the writing. On the other hand, with regard to second variable-resistance nonvolatile storage element 20 having conductance that gradually changes by successive applications of a voltage pulse with the same polarity and the same voltage, the conductance thereof gently changes. Thus, a degree of deterioration of second variable-resistance nonvolatile storage element 20 due to the writing itself is low, so that the endurance property thereof is considered to be high.

### [Arrangement of Variable-Resistance Nonvolatile Storage Elements]

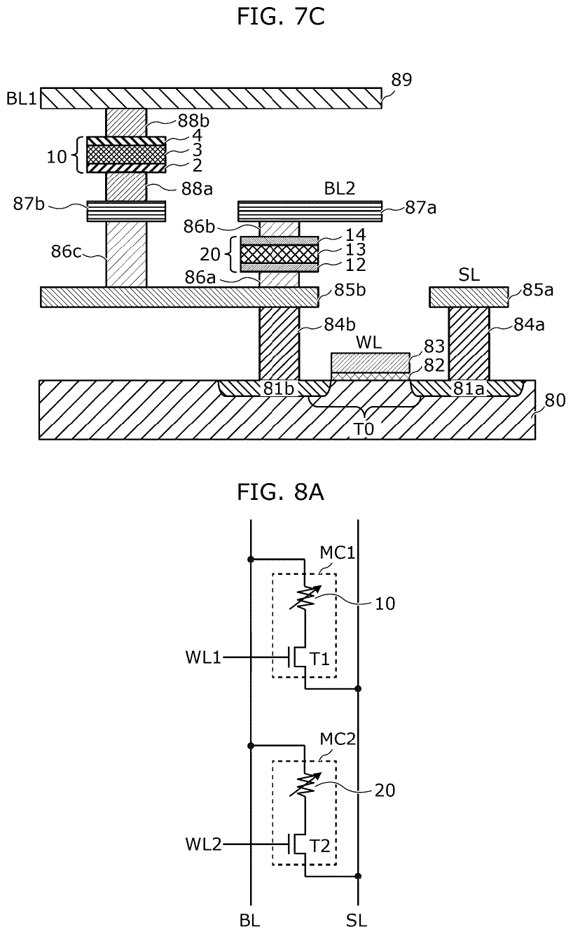

FIG. 6A and FIG. 6B are a circuit diagram and a cross sectional view, respectively, of a variable-resistance nonvolatile storage element according to a conventional technique.

FIG. 6A is a circuit diagram of a memory cell of an AI processing device provided with a conventional variable-resistance nonvolatile storage element. Memory cell MC includes variable-resistance nonvolatile storage element RP and cell transistor T0 connected in series, and is a “1T1R” memory cell that includes single cell transistor T0 and single variable-resistance nonvolatile storage element RP. Word line WL of memory cell MC is connected to the gate terminal of cell transistor T0, bit line BL is connected to variable-resistance nonvolatile storage element RP, and source line SL is connected to the source terminal of cell transistor T0.

FIG. 6B is a cross sectional view of the memory cell of the AI processing device provided with conventional variable-resistance nonvolatile storage element RP. Diffuse regions 61a and 61b are provided in substrate 60, and diffuse region 61a functions as a source terminal of cell transistor T0, whereas diffuse region 61b functions as a drain terminal of cell transistor T0. A portion between diffuse regions 61a and 61b functions as a channel region of cell transistor T0. Oxide film 62 and gate electrode 63 made of polysilicon are provided above the channel region and operate as cell transistor T0. Diffuse region 61a that is a source terminal of cell transistor T0 is connected to source line SL that is first wiring layer 65a with via 64a being provided therebetween. Diffuse region 61b that is a drain terminal of cell transistor T0 is connected to first wiring layer 65b with via 64b being provided therebetween. Furthermore, first wiring layer 65b is connected to second wiring layer 67 with via 66 being provided therebetween, and second wiring layer 67 is connected to variable-resistance nonvolatile storage element RP with via 68a being provided therebetween. Variable-resistance nonvolatile storage element RP includes first electrode 2, variable resistance layer 3, and second electrode 4. Variable-resistance nonvolatile storage element RP is connected to bit line BL that is third wiring layer 69 with via 68b being provided therebetween.

With this configuration, the AI processing device includes, as variable-resistance nonvolatile storage element RP, only one of first variable-resistance nonvolatile storage element 10 according to the embodiment, which has conductance that substantially reaches the set conductance by a single application of a voltage pulse, or second variable-resistance nonvolatile storage element 20 according to the embodiment, which has conductance that gradually changes by successive applications of a voltage pulse with the same polarity and the same voltage. Accordingly, it is difficult to achieve both of setting a connection weight coefficient (initial setting) with high efficiency and high accuracy at the time of product shipment, for instance, and updating a connection weight coefficient (training) with high efficiency after product shipment, for instance.

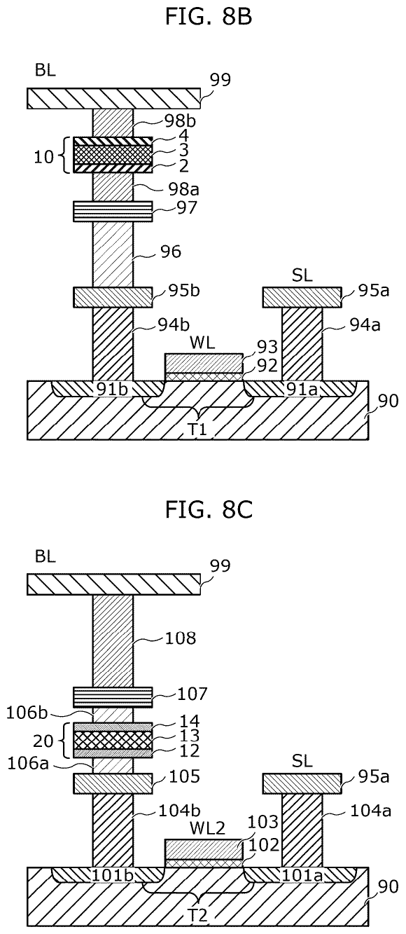

FIG. 7A to FIG. 7C are a circuit diagram, an example of a cross sectional view, and another example of a cross sectional view, respectively, of the variable-resistance nonvolatile storage elements according to the embodiment.

FIG. 7A is a circuit diagram of a memory cell of an AI processing device that includes both first variable-resistance nonvolatile storage element 10 and second variable-resistance nonvolatile storage element 20. Memory cell MC includes first variable-resistance nonvolatile storage element 10, second variable-resistance nonvolatile storage element 20, and cell transistor T0 that are connected, and is a “1T2R” memory cell that includes single cell transistor T0 and two variable-resistance nonvolatile storage elements, first variable-resistance nonvolatile storage element 10 having conductance that can be set by a single application of a voltage pulse, second variable-resistance nonvolatile storage element 20 having conductance that gradually changes by successive applications of a voltage pulse with the same polarity and the same voltage. Word line WL of memory cell MC is connected to the gate terminal of cell transistor T0, bit line BL1 is connected to first variable-resistance nonvolatile storage element 10, bit line BL2 is connected to second variable-resistance nonvolatile storage element 20, and source line SL is connected to the source terminal of cell transistor T0.

FIG. 7B illustrates an example of a cross sectional view of the memory cell of the AI processing device that includes both first variable-resistance nonvolatile storage element 10 and second variable-resistance nonvolatile storage element 20, which are illustrated in FIG. 7A. Diffuse regions 71a and 71b are provided in semiconductor substrate 70, and diffuse region 71a functions as a source terminal of cell transistor T0, whereas diffuse region 71b functions as a drain terminal of cell transistor T0. A portion between diffuse regions 71a and 71b functions as a channel region of cell transistor T0. Oxide film 72 and gate electrode 73 made of polysilicon are provided above the channel region and operate as cell transistor T0. Diffuse region 71a that is a source terminal of cell transistor T0 is connected to source line SL that is first wiring layer 75a with via 74a being provided therebetween. Diffuse region 71b that is a drain terminal of cell transistor T0 is connected to first wiring layer 75b with via 74b being provided therebetween. Furthermore, first wiring layer 75b is connected to second wiring layer 77 with via 76a being provided therebetween, and second wiring layer 77 is connected to first variable-resistance nonvolatile storage element 10 with via 78a being provided therebetween. First variable-resistance nonvolatile storage element 10 includes first electrode 2, variable resistance layer 3, and second electrode 4. First variable-resistance nonvolatile storage element 10 is connected to bit line BL1 that is third wiring layer 79 with via 78b being provided therebetween. Simultaneously, second wiring layer 77 is connected to second variable-resistance nonvolatile storage element 20 with via 76c being provided therebetween. Second variable-resistance nonvolatile storage element 20 includes first electrode 12, variable resistance layer 13, and second electrode 14. Second variable-resistance nonvolatile storage element 20 is connected to bit line BL2 that is first wiring layer 75c with via 76b being provided therebetween.

FIG. 7C illustrates an example of a cross sectional view of a memory cell of the AI processing device that includes both first variable-resistance nonvolatile storage element 10 and second variable-resistance nonvolatile storage element 20, which are illustrated in FIG. 7A, and is different from the previous example (that is, the example illustrated in FIG. 7B). Diffuse regions 81a and 81b are provided in semiconductor substrate 80, and diffuse region 81a functions as a source terminal of cell transistor T0, whereas diffuse region 81b functions as a drain terminal of cell transistor T0. A portion between diffuse regions 81a and 81b functions as a channel region of cell transistor T0. Oxide film 82 and gate electrode 83 made of polysilicon are provided above the channel region and operate as cell transistor T0. Diffuse region 81a that is a source terminal of cell transistor T0 is connected to source line SL that is first wiring layer 85a with via 84a being provided therebetween. Diffuse region 81b that is a drain terminal of cell transistor T0 is connected to first wiring layer 85b with via 84b being provided therebetween. Furthermore, first wiring layer 85b is connected to second wiring layer 87b with via 86c being provided therebetween, and second wiring layer 87b is connected to first variable-resistance nonvolatile storage element 10 with via 88a being provided therebetween. First variable-resistance nonvolatile storage element 10 includes first electrode 2, variable resistance layer 3, and second electrode 4. First variable-resistance nonvolatile storage element 10 is connected to bit line BL1 that is third wiring layer 89 with via 88b being provided therebetween. Simultaneously, first wiring layer 85b is connected to second variable-resistance nonvolatile storage element 20 with via 86a being provided therebetween. Second variable-resistance nonvolatile storage element 20 includes first electrode 12, variable resistance layer 13, and second electrode 14. Second variable-resistance nonvolatile storage element 20 is connected to bit line BL2 that is second wiring layer 87a with via 86b being provided therebetween. With this arrangement, in a view in a direction perpendicular to the plane of the substrate, the center of first variable-resistance nonvolatile storage element 10 and the center of second variable-resistance nonvolatile storage element 20 do not coincide.

Note that in FIG. 7B and FIG. 7C, first variable-resistance nonvolatile storage element 10 and second variable-resistance nonvolatile storage element 20 are provided between different pairs of wiring layers included in the wiring layers from the first wiring layer to the third wiring layer, but similar effects can be achieved even when first variable-resistance nonvolatile storage element 10 and second variable-resistance nonvolatile storage element 20 are provided between different pairs of wiring layers included in other wiring layers, for example, from, the second wiring layer to a forth wiring layer.

In FIG. 6A that illustrates a conventional example, a current that flows through bit line BL or source line SL, that is, a current that flows through variable-resistance nonvolatile storage element RP is defined as a current flowing through memory cell MC. But nevertheless, in FIG. 7A showing the present embodiment, a current that flows through memory cell MC is defined as a total of a current flowing through bit line BL1 and a current flowing through bit line BL2 or a current flowing through source line SL, that is, a total of a current flowing through first variable-resistance nonvolatile storage element 10 and a current flowing through second variable-resistance nonvolatile storage element 20.

In memory cell MC illustrated in FIG. 7A to FIG. 7C, a signal in word line WL corresponds to an input signal input to one neuron, a total of conductance of first variable-resistance nonvolatile storage element 10 and conductance of second variable-resistance nonvolatile storage element 20 corresponds to a connection weight coefficient corresponding to the input signal, and a total of currents flowing through first variable-resistance nonvolatile storage element 10 and second variable-resistance nonvolatile storage element 20 (that is, a total of currents flowing through bit line BL1 and bit line BL2 or a current flowing through source line SL) corresponds to a product of the input signal and the connection weight coefficient.

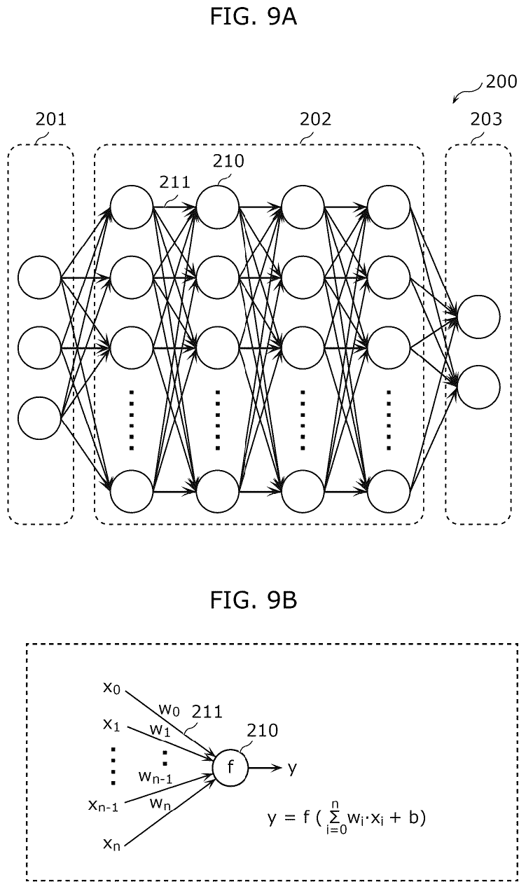

FIG. 8A to FIG. 8C are a circuit diagram, an example of a cross sectional view, and another example of a cross sectional view, respectively, of variable-resistance nonvolatile storage elements according to another embodiment.

FIG. 8A is a circuit diagram of a memory cell of the AI processing device that includes both first variable-resistance nonvolatile storage element 10 and second variable-resistance nonvolatile storage element 20. Memory cell MC1 includes a connected series of first variable-resistance nonvolatile storage element 10 and cell transistor T1, and memory cell MC2 includes a connected series of second variable-resistance nonvolatile storage element 20 and cell transistor T2, first variable-resistance nonvolatile storage element 10 having conductance that can be set by a single application of a voltage pulse, second variable-resistance nonvolatile storage element 20 having conductance that gradually changes by successive applications of a voltage pulse with the same polarity and the same voltage. Memory cells MC1 and MC2 constitute a “2T2R” memory cell that includes two cell transistors T1 and T2 and two variable-resistance nonvolatile storage elements. Word line WL1 of memory cell MC1 is connected to the gate terminal of cell transistor T1, word line WL2 of memory cell MC2 is connected to the gate terminal of cell transistor T2, bit line BL is connected to first variable-resistance nonvolatile storage element 10 and second variable-resistance nonvolatile storage element 20, and source line SL is connected to the source terminals of cell transistors T1 and T2.

FIG. 8B illustrates an example of a cross sectional view of memory cell MC1 of the AI processing device that includes first variable-resistance nonvolatile storage element 10 illustrated in FIG. 8A. Diffuse regions 91a and 91b are provided in semiconductor substrate 90, and diffuse region 91a functions as a source terminal of cell transistor T1, whereas diffuse region 91b functions as a drain terminal of cell transistor T1. A portion between diffuse regions 91a and 91b functions as a channel region of cell transistor T1. Oxide film 92 and gate electrode 93 made of polysilicon are provided above the channel region and operate as cell transistor T1. Diffuse region 91a that is a source terminal of cell transistor T1 is connected to source line SL that is first wiring layer 95a with via 94a being provided therebetween. Diffuse region 91b that is a drain terminal of cell transistor T1 is connected to first wiring layer 95b with via 94b being provided therebetween. Furthermore, first wiring layer 95b is connected to second wiring layer 97 with via 96 being provided therebetween, and second wiring layer 97 is connected to first variable-resistance nonvolatile storage element 10 with via 98a being provided therebetween. First variable-resistance nonvolatile storage element 10 includes first electrode 2, variable resistance layer 3, and second electrode 4. First variable-resistance nonvolatile storage element 10 is connected to bit line BL that is third wiring layer 99 with via 98b being provided therebetween.

FIG. 8C illustrates an example of a cross sectional view of memory cell MC2 of the AI processing device that includes second variable-resistance nonvolatile storage element 20 illustrated in FIG. 8A. Diffuse regions 101a and 101b are provided in substrate 90 that is common to FIG. 8B, and diffuse region 101a functions as a source terminal of cell transistor T2, whereas diffuse region 101b functions as a drain terminal of cell transistor T2. A portion between diffuse regions 101a and 101b functions as a channel region of cell transistor T2. Oxide film 102 and gate electrode 103 made of polysilicon are provided above the channel region and operate as cell transistor T2. Diffuse region 101a that is a source terminal of cell transistor T2 is connected to source line SL that is first wiring layer 95a that is common to FIG. 8B with via 104a being provided therebetween. Diffuse region 101b that is a drain terminal of cell transistor T2 is connected to first wiring layer 105 with via 104b being provided therebetween. First wiring layer 105 is connected to second variable-resistance nonvolatile storage element 20 with via 106a being provided therebetween. Second variable-resistance nonvolatile storage element 20 includes first electrode 12, variable resistance layer 13, and second electrode 14. Second variable-resistance nonvolatile storage element 20 is connected to second wiring layer 107 with via 106b being provided therebetween. Second wiring layer 107 is connected to bit line BL that is third wiring layer 99 common to FIG. 8B with via 108 being provided therebetween.

Note that in FIG. 8B and FIG. 8C, first variable-resistance nonvolatile storage element 10 and second variable-resistance nonvolatile storage element 20 are provided between different pairs of wiring layers included in the wiring layers from the first wiring layer to the third wiring layer, but similar effects can be achieved even when first variable-resistance nonvolatile storage element 10 and second variable-resistance nonvolatile storage element 20 are provided between different pairs of wiring layers included in other wiring layers, for example, from the second wiring layer to the forth wiring layer.

In FIG. 6A that illustrates a conventional example, a current that flows through bit line BL or source line SL, that is, a current that flows through variable-resistance nonvolatile storage element RP is defined as a current flowing through memory cell MC. But nevertheless, in FIG. 8A showing the present embodiment, a current that flows through bit line BL or a current that flows through source line SL is defined as a total of a current flowing through memory cell MC1 and a current flowing through memory cell MC2, that is, a total of a current flowing through first variable-resistance nonvolatile storage element 10 and a current flowing through second variable-resistance nonvolatile storage element 20.

When focusing on memory cells that are a combination of memory cell MC1 and memory cell MC2 illustrated in FIG. 8A to FIG. 8C, a common signal that passes through word lines WL1 and WL2 corresponds to an input signal input to one neuron, a total of conductance of first variable-resistance nonvolatile storage element 10 and conductance of second variable-resistance nonvolatile storage element 20 corresponds to a connection weight coefficient corresponding to the input signal, and a total of currents flowing through first variable-resistance nonvolatile storage element 10 and second variable-resistance nonvolatile storage element 20 (that is, a current flowing through bit line BL or a current flowing through source line SL) corresponds to a product of the input signal and the connection weight coefficient.

As illustrated in FIG. 7A to FIG. 7C and FIG. 8A to FIG. 8C, in the AI processing device according to the embodiment, which includes both first variable-resistance nonvolatile storage element 10 having conductance that substantially reaches the set conductance by a single application of a voltage pulse and second variable-resistance nonvolatile storage element 20 having conductance that gradually changes by successive applications of a voltage pulse with the same polarity and the same voltage, both of the elements can be used. Thus, first variable-resistance nonvolatile storage element 10 changes its conductance at least one of (i) when firmware is updated before or after product shipment, (ii) when a learning model is updated, (iii) when regular maintenance is performing, or (iv) when the connection weight coefficient is insufficiently updated by changing the conductance of second variable-resistance nonvolatile storage element 20, whereas second variable-resistance nonvolatile storage element 20 changes its conductance in updating the connection weight coefficient for training after product shipment. Since such usage is adopted, both of setting a connection weight coefficient (initial setting) with high efficiency and accuracy after product shipment, for instance, and updating a connection weight coefficient (training) with high efficiency after product shipment, for instance, can be achieved. Thus, when a connection weight coefficient is to be changed (that is, written to), according to a purpose at that time, conductance of only one of first variable-resistance nonvolatile storage element 10 or second variable-resistance nonvolatile storage element 20 is changed, and a total value of currents flowing through both of first variable-resistance nonvolatile storage element 10 and second variable-resistance nonvolatile storage element 20 is used when inference is made using an AI processing device (that is, the connection weight coefficient is read out).

In an AI processing device, when there are a first neural network region in which a connection weight coefficient setting of an existing neural network is used as-is with the application of transfer learning or reinforcement learning in which the connection weight coefficient setting of the existing neural network is used and a second neural network region that is newly trained, transfer learning or reinforcement learning can be efficiently performed, by the usage that the conductance of first variable-resistance nonvolatile storage element 10 is changed to set a connection weight coefficient for the first neural network region and the conductance of second variable-resistance nonvolatile storage element 20 is changed to set a connection weight coefficient for the second neural network.

### Example

Next, Example of an AI processing device according to the present disclosure is to be explained.

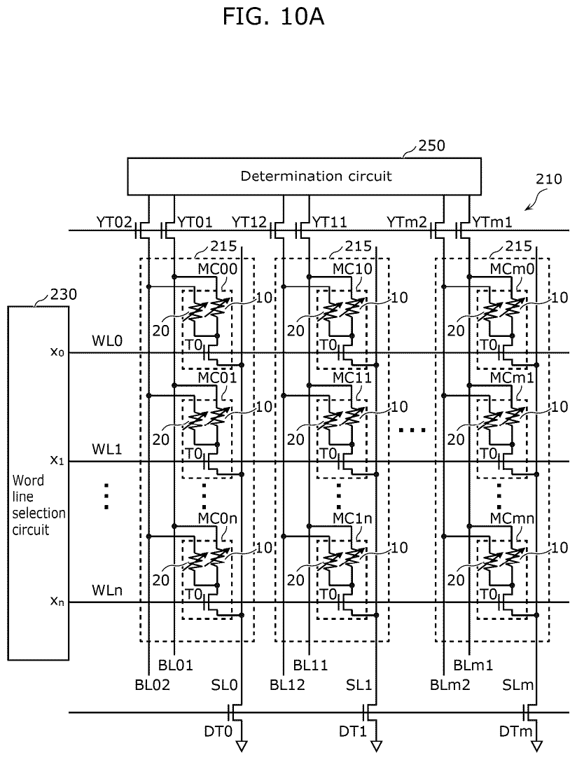

FIG. 9A is a block diagram illustrating a model of AI processing device 200 according to Example. AI processing device 200 is a neural network that includes: input layer 201, plural hidden layers 202, and output layer 203. The layers (input layer 201, hidden layers 202, and output layer 203) each include plural neurons 210. Neurons 210 each receive an input of output data from neuron 210 included in a layer in a previous stage, via synapse 211.

FIG. 9B illustrates functions of neuron 210 illustrated in FIG. 9A. Neuron 210 receives, as input data xᵢ, output data from neuron 210 included in a layer in a previous stage via synapse 211, and performs multiply-accumulate operation (Σwᵢ·xᵢ) in which products (wᵢ·xᵢ) resulting from multiplying each of all received input data items xᵢ by connection weight coefficient wᵢ corresponding to synapse 211 are added. Neuron 210 adds bias b included inside to the result of the multiply-accumulate operation, generates output data y by inputting the obtained result (Σwᵢ·xᵢ+b) to activation function f such as a step function included inside, and outputs output data y to neurons 210 included in a layer in the next stage.

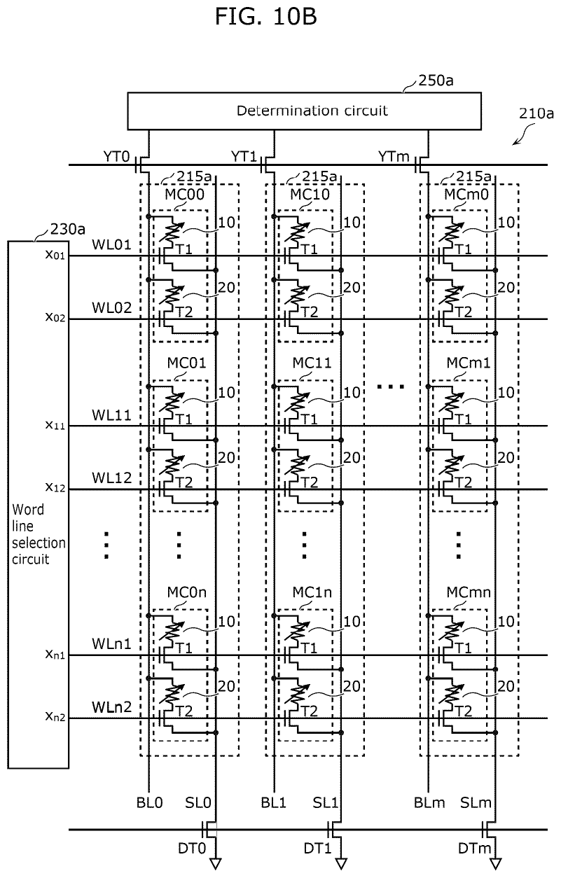

FIG. 10A illustrates an example of a circuit that implements neurons 210 illustrated in FIG. 9B. This drawing illustrates an example of a circuit in which 1T2R memory cells MC each illustrated in FIG. 7A are used as memory cells MCij (i=0 to m, j=0 to n) disposed two-dimensionally. Neurons 210 each include multiply-accumulate operation circuit 215, word line selection circuit 230, determination circuit 250, and column gates (transistors YTi1 and YTi2 and transistors DTi).

Multiply-accumulate operation circuit 215 is a circuit that performs a multiply-accumulate operation in neuron 210 and in which 1T2R memory cells illustrated in FIG. 7A are arranged in the column direction and are connected to one another by sharing bit lines BLi1 and BLi2 and source line SLi. Currents output from memory cells each correspond to a product (wᵢ·xᵢ) of input data xᵢ and connection weight coefficient wᵢ, and are combined. A current flowing through source line SLi (or alternatively, a total of currents flowing through bit lines BLi1 and BLi2) corresponds to result Σwᵢ·xᵢ of the multiply-accumulate operation. In multiply-accumulate operation circuit 215, input data xᵢ is “1” or “0”, and connection weight coefficient wᵢ corresponds to a total of conductance of first variable-resistance nonvolatile storage element 10 and conductance of second variable-resistance nonvolatile storage element 20.

Note that in this drawing, plural multiply-accumulate operation circuits 215 for all neurons 210 illustrated in FIG. 9A are disposed in the row direction, and one of multiply-accumulate operation circuits 215 performs multiply-accumulate operation in one neuron 210.

Word line selection circuit 230 supplies the gate terminals of transistors Ti included in memory cells MCi0 to MCin included in multiply-accumulate operation circuits 215 with input data items x0 to xn for selecting or not selecting memory cells in row units via word lines WL0 to WLn.

Determination circuit 250 executes activation function f that neuron 210 has, compares a predetermined threshold with a value (Σwᵢ·xᵢ+b) obtained by adding bias b included inside to a current flowing through source line SLi and indicating the result of a multiply-accumulate operation output from multiply-accumulate operation circuit 215 or to a total of currents (Σwᵢ·xᵢ) flowing through bit lines BLi1 and BLi2, and outputs the result of the comparison. Determination circuit 250 can perform processing in parallel for multiply-accumulate operation circuits 215 disposed in the row direction.

In writing to and reading out from memory cells MCi0 to MCin, transistors YTi1 and YTi2 included in the column gates connect and disconnect a predetermined power supply voltage line to/from bit lines BLi1 and BLi2 of memory cells MCi0 to MCin, according to signals input to the gate terminals. In writing to and reading out from memory cells MCi0 to MCin, transistor DTi connects and disconnects the predetermined power supply voltage line to/from source line SLi, according to a signal input to the gate terminal.

FIG. 10B illustrates an example of another circuit that implements neurons 210 illustrated in FIG. 9B (neurons 210a). In this drawing, as memory cells MCij (i=0 to m, j=0 to n) two-dimensionally disposed, 2T2R memory cells MC illustrated in FIG. 8A are disposed in the column direction, and connected to one another by sharing bit line BLi and source line SLi. Neurons 210a each include multiply-accumulate operation circuit 215a, word line selection circuit 230a, determination circuit 250a, and column gates (transistors YTi and transistors DTi).

Neuron 210a has basic functions same as those of neuron 210 illustrated in FIG. 10A, and a connection configuration corresponding to 2T2R memory cell MCij, unlike neuron 210 in FIG. 10A that includes 1T2R memory cells MCij. Word line selection circuit 230a outputs signals to two word lines WLj1 and WLj2, for memory cells MCi0 to MCin. Determination circuit 250a compares a predetermined threshold with a value (Σwᵢ·xᵢ+b) obtained by adding bias b included inside to a current (Σwᵢ·xᵢ) flowing through bit line BLi or source line SLi and indicating the result of a multiply-accumulate operation output from multiply-accumulate operation circuit 215a, and outputs the result of the comparison. For each of the column gates, one transistor YTi that switches between connection to and disconnection from the predetermined power supply voltage line is provided for each bit line BLi.

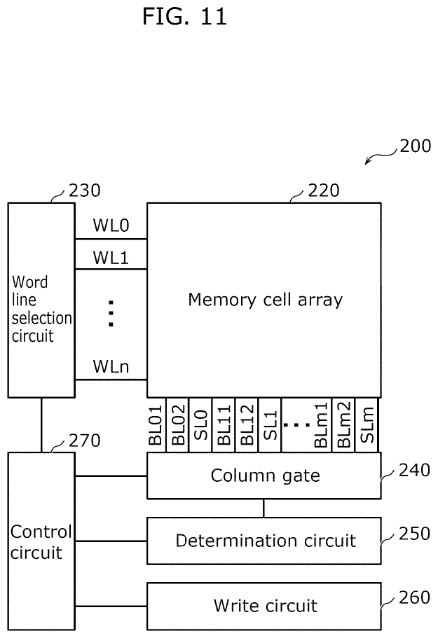

FIG. 11 is a block diagram illustrating the entire configuration of AI processing device 200 that includes neurons 210 illustrated in FIG. 10A. AI processing device 200 includes memory cell array 220, word line selection circuit 230, column gate 240, determination circuit 250, write circuit 260, and control circuit 270.

Memory cell array 220 corresponds to memory cells MCij (i=0 to m, j=0 to n) illustrated in FIG. 10A. Word line selection circuit 230, column gate 240, and determination circuit 250 are the same as those explained in FIG. 10A. Write circuit 260 supplies a predetermined power supply voltage explained in FIG. 10A, and includes a current limiting circuit for writing predetermined conductance (or stated differently, multi-tone analog resistance) to memory cells MCij.

Control circuit 270 is a circuit that controls writing to and reading out from memory cells MCij by controlling the entirety of AI processing device 200, and includes a processor and memory that stores therein programs, for example. More specifically, when changing (that is, writing) a connection weight coefficient of AI processing device 200, control circuit 270 controls AI processing device 200 to change conductance of only one of first variable-resistance nonvolatile storage element 10 or second variable-resistance nonvolatile storage element 20 included in each memory cell MCij, according to a purpose for setting a connection weight coefficient (initial setting) with high accuracy at the time of product shipment, for instance, or for updating a connection weight coefficient (training) with high efficiency after product shipment, for instance. When inference is made using AI processing device 200 (that is, using a connection weight coefficient), control circuit 270 controls AI processing device 200 to use a total value of currents flowing through first variable-resistance nonvolatile storage element 10 and second variable-resistance nonvolatile storage element 20 included in each memory cell MCij.

Note that FIG. 11 is a block diagram illustrating a configuration of the entirety of AI processing device 200 that includes neurons 210 illustrated in FIG. 10A, but a block diagram illustrating a configuration of the entirety of AI processing device 200 that includes neurons 210a illustrated in FIG. 10B is similar to FIG. 11 except for, for instance, the connecting lines explained above, and thus illustration and explanation of the block diagram are omitted.

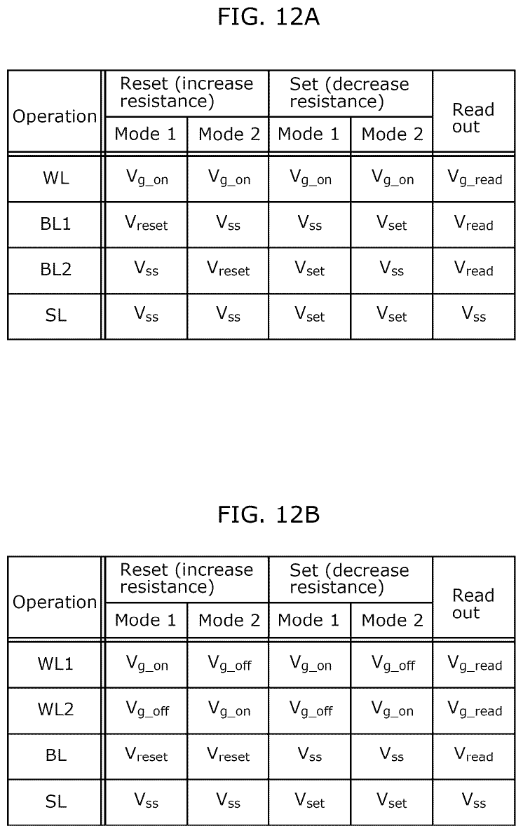

FIG. 12A illustrates examples of applied voltages via word line WL, bit lines BL1 and BL2, and source line SL, in writing to and reading out from memory cell MCij illustrated in FIG. 10A. Here, the drawing shows examples of applied voltages in the cases where first variable-resistance nonvolatile storage element 10 and second variable-resistance nonvolatile storage element 20 included in memory cell MCij in the i-th column are reset (the resistances are increased) and are set (the resistances are decreased) and in the case of reading out from memory cell MCij. In FIG. 12A, “Mode 1” shows writing conductance to first variable-resistance nonvolatile storage element 10 (a first rewriting step), whereas “Mode 2” shows writing conductance to second variable-resistance nonvolatile storage element 20 (a second rewriting step). Note that “writing to memory cell MCij” means setting or changing a connection weight coefficient in memory cell MCij, and “reading out from memory cell MCij” means measuring a current flowing through memory cell MCij.

### (1) When Writing to Memory Cell MCij (Setting or Changing Connection Weight Coefficient)

When first variable-resistance nonvolatile storage element 10 is to be reset (“the resistance is increased”) (“Mode 1”), pulse voltage V_{g_on} (for example, 2V) that turns on transistor Ti is supplied to the gate terminal via word line WL, reset voltage Vᵣₑₛₑₜ (for example, 2V) is applied to bit line BL1, reference voltage Vₛₛ (for example, 0V) is applied to bit line BL2, and reference voltage Vₛₛ (for example, 0V) is applied to source line SL. Accordingly, a positive voltage is applied to an upper terminal of only first variable-resistance nonvolatile storage element 10 with respect to the lower terminal thereof, and the resistance of first variable-resistance nonvolatile storage element 10 is increased to a resistance according to a limited current by the current limiting circuit included in write circuit 260.

When second variable-resistance nonvolatile storage element 20 is to be reset (“the resistance is increased”) (“Mode 2”), pulse voltage V_{g_on} (for example, 2V) that turns on transistor Ti is supplied to the gate terminal via word line WL, reference voltage Vₛₛ (for example, 0V) is applied to bit line BL1, reset voltage Vᵣₑₛₑₜ (for example, 2V) is applied to bit line BL2, and reference voltage Vₛₛ (for example, 0V) is applied to source line SL. Accordingly, a positive voltage is applied to an upper terminal of only second variable-resistance nonvolatile storage element 20 with respect to the lower terminal thereof, and the resistance of second variable-resistance nonvolatile storage element 20 is increased to a resistance according to a limited current by the current limiting circuit included in write circuit 260.

When first variable-resistance nonvolatile storage element 10 is to be set (“the resistance is decreased”) (“Mode 1”), pulse voltage V_{g_on} (for example, 2V) that turns on transistor Ti is supplied to the gate terminal via word line WL, reference voltage Vₛₛ (for example, 0V) is applied to bit line BL1, set voltage Vₛₑₜ (for example, 2V) is applied to bit line BL2, and set voltage Vₛₑₜ (for example, 2V) is applied to source line SL. Accordingly, a negative voltage is applied to an upper terminal of only first variable-resistance nonvolatile storage element 10 with respect to the lower terminal thereof, and the resistance of first variable-resistance nonvolatile storage element 10 is decreased to a resistance according to a limited current by the current limiting circuit included in write circuit 260.

When second variable-resistance nonvolatile storage element 20 is to be set (“the resistance is decreased”) (“Mode 2”), pulse voltage V_{g_on} (for example, 2V) that turns on transistor Ti is supplied to the gate terminal via word line WL, set voltage Vₛₑₜ (for example, 2V) is applied to bit line BL1, reference voltage Vₛₛ (for example, 0V) is applied to bit line BL2, and set voltage Vₛₑₜ (for example, 2V) is applied to source line SL. Accordingly, a negative voltage is applied to an upper terminal of only second variable-resistance nonvolatile storage element 20 with respect to the lower terminal thereof, and the resistance of second variable-resistance nonvolatile storage element 20 is decreased to a resistance according to a limited current by the current limiting circuit included in write circuit 260.

(2) Reading Out from Memory Cell MCij (Inference Step)

When a total of currents flowing though first variable-resistance nonvolatile storage element 10 and second variable-resistance nonvolatile storage element 20 is to be measured (“reading out”), readout voltage V_{g_read} that turns on transistor Ti (for example, 1V) is supplied to the gate terminal via word line WL, readout voltage V_{read} (for example, 0.4V) is applied to bit lines BL1 and BL2, and reference voltage Vₛₛ (for example, 0V) is applied to source line SL. Accordingly, readout voltage V_{read} is applied to first variable-resistance nonvolatile storage element 10 and second variable-resistance nonvolatile storage element 20, and a total of currents flowing through first variable-resistance nonvolatile storage element 10 and second variable-resistance nonvolatile storage element 20 (that is, one product (wᵢ·xᵢ)) is output from memory cell MCij. Thus, currents output from all of memory cells MCij included in multiply-accumulate operation circuit 215 flow through source line SL (the currents correspond to a total of currents flowing through bit lines BL1 and BL2), and are measured by determination circuit 250 as a result (Σwᵢ·xᵢ) of the multiply-accumulate operation.

FIG. 12B illustrates examples of applied voltages via word lines WL1 and WL2, bit line BL, and source line SL, in writing to and reading out from memory cell MCij illustrated in FIG. 10B. Here, the drawing shows examples of applied voltages in the cases where first variable-resistance nonvolatile storage element 10 and second variable-resistance nonvolatile storage element 20 included in memory cell MCij in the i-th column are reset (the resistances are increased) and are set (the resistances are decreased) and in the case of reading out from memory cell MCij.

### (1) When Writing to Memory Cell MCij (Setting or Changing Connection Weight Coefficient)

When first variable-resistance nonvolatile storage element 10 is to be reset (“the resistance is increased”) (“Mode 1”), pulse voltage V_{g_on} (for example, 2V) that turns on transistor Ti1 is supplied to the gate terminal via word line WL1, pulse voltage V_{g_off} (for example, 0V) that turns off transistor Ti2 is supplied to the gate terminal via word line WL2, reset voltage Vᵣₑₛₑₜ (for example, 2V) is applied to bit line BL, and reference voltage Vₛₛ (for example, 0V) is applied to source line SL. Accordingly, a positive voltage is applied to an upper terminal of only first variable-resistance nonvolatile storage element 10 with respect to the lower terminal thereof, and the resistance of first variable-resistance nonvolatile storage element 10 is increased to a resistance according to a limited current by the current limiting circuit included in write circuit 260.

When second variable-resistance nonvolatile storage element 20 is to be reset (“the resistance is increased”) (“Mode 2”), pulse voltage V_{g_off} (for example, 0V) that turns off transistor Ti1 is supplied to the gate terminal via word line WL1, pulse voltage V_{g_on} (for example, 2V) that turns on transistor Ti2 is supplied to the gate terminal via word line WL2, reset voltage Vᵣₑₛₑₜ (for example, 2V) is applied to bit line BL, and reference voltage Vₛₛ (for example, 0V) is applied to source line SL. Accordingly, a positive voltage is applied to an upper terminal of only second variable-resistance nonvolatile storage element 20 with respect to the lower terminal thereof, and the resistance of second variable-resistance nonvolatile storage element 20 is increased to a resistance according to a limited current by the current limiting circuit included in write circuit 260.

When first variable-resistance nonvolatile storage element 10 is to be set (“the resistance is decreased”) (“Mode 1”), pulse voltage V_{g_on} (for example, 2V) that turns on transistor Ti1 is supplied to the gate terminal via word line WL1, pulse voltage V_{g_off} (for example, 0V) that turns off transistor Ti2 is supplied to the gate terminal via word line WL2, reference voltage Vₛₛ (for example, 0V) is applied to bit line BL, and set voltage Vₛₑₜ (for example, 2V) is applied to source line SL. Accordingly, a negative voltage is applied to an upper terminal of only first variable-resistance nonvolatile storage element 10 with respect to the lower terminal thereof, and the resistance of first variable-resistance nonvolatile storage element 10 is decreased to a resistance according to a limited current by the current limiting circuit included in write circuit 260.

When second variable-resistance nonvolatile storage element 20 is to be set (“the resistance is decreased”) (“Mode 2”), pulse voltage V_{g_off} (for example, 0V) that turns off transistor Ti1 is supplied to the gate terminal via word line WL1, pulse voltage V_{g_on} (for example, 2V) that turns on transistor Ti2 is supplied to the gate terminal via word line WL2, reference voltage Vₛₛ (for example, 0V) is applied to bit line BL, and set voltage Vₛₑₜ (for example, 2V) is applied to source line SL. Accordingly, a negative voltage is applied to an upper terminal of only second variable-resistance nonvolatile storage element 20 with respect to the lower terminal thereof, and the resistance of second variable-resistance nonvolatile storage element 20 is decreased to a resistance according to a limited current by the current limiting circuit included in write circuit 260.

(2) Reading Out from Memory Cell MCij (Inference Step)

When a total of currents flowing though first variable-resistance nonvolatile storage element 10 and second variable-resistance nonvolatile storage element 20 is to be measured (“reading out”), readout voltage V_{g_read} (for example, 1V) that turns on transistors Ti1 and Ti2 is supplied to the gate terminal via word lines WL1 and WL2, readout voltage V_{read} (for example, 0.4V) is applied to bit line BL, and reference voltage Vₛₛ (for example, 0V) is applied to source line SL. Accordingly, readout voltage V_{read} is applied to first variable-resistance nonvolatile storage element 10 and second variable-resistance nonvolatile storage element 20, and currents flowing through first variable-resistance nonvolatile storage element 10 and second variable-resistance nonvolatile storage element 20 (a total of the currents corresponds to one product (wᵢ·xᵢ)) is output from memory cell MCij. Thus, currents output from all of memory cells MCij included in multiply-accumulate operation circuit 215 flow through source line SL and bit line BL, and are measured by determination circuit 250 as a result (Σwᵢ·xᵢ) of the multiply-accumulate operation.

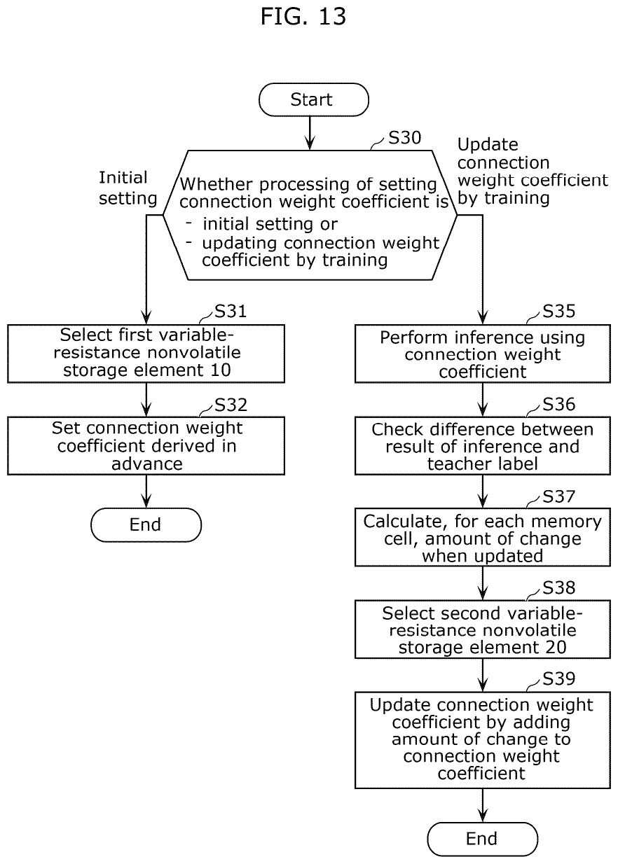

FIG. 13 is a flowchart illustrating an example of operation of control circuit 270 illustrated in FIG. 11.

Control circuit 270 determines whether processing of setting a connection weight coefficient to be performed from now is a first case in which a connection weight coefficient is changed for initial setting or a second case in which a connection weight coefficient is changed by training (S30). Note that the first case includes at least one of (i) a case where firmware is updated before or after shipping AI processing device 200, (ii) a case where a learning model is updated, (iii) a case where regular maintenance is performed, or (iv) a case where a connection weight coefficient is insufficiently updated by changing conductance of second variable-resistance nonvolatile storage element 20, whereas the second case includes a case where a connection weight coefficient for training after shipping AI processing device 200.

As a result, when control circuit 270 determines that the processing of setting a connection weight coefficient is initial setting (that is, the first case) (“initial setting” in S30), for each memory cell MCij, control circuit 270 selects first variable-resistance nonvolatile storage element 10 (S31) and sets a connection weight coefficient derived in advance (S32), by controlling column gate 240 or word line selection circuit 230. Thus, control circuit 270 writes, for each memory cell MCij, the conductance derived in advance to first variable-resistance nonvolatile storage element 10 (that is, in “Mode 1”) (first rewrite step).

On the other hand, in step S30, when control circuit 270 determines that the processing of setting a connection weight coefficient is updating a connection weight coefficient by training (that is, the second case) (“Updating connection weight coefficient by training” in S30), control circuit 270 performs inference using a connection weight coefficient held in current memory cell array 220 (S35), checks a difference between the result of the inference and a teacher label (S36), and thereafter calculates, for each memory cell MCij, an amount of change in connection weight coefficient when updated (S37). By controlling column gate 240 or word line selection circuit 230, for each memory cell MCij, control circuit 270 selects second variable-resistance nonvolatile storage element 20 (S38), and updates a connection weight coefficient to change the current connection weight coefficient by an amount of change in the calculated connection weight coefficient (S39). Thus, control circuit 270 updates, for each memory cell MCij, the conductance of second variable-resistance nonvolatile storage element 20 by the amount of change (that is, in “Mode 2”) (second rewrite step).

Accordingly, according to a purpose for initial setting or training, writing is performed on only one of first variable-resistance nonvolatile storage element 10 or second variable-resistance nonvolatile storage element 20 suitable for the purpose, setting a connection weight coefficient (initial setting) with high accuracy at the time of product shipment, for instance, and updating a connection weight coefficient (training) with high efficiency after product shipment, for instance, can be both achieved.

Note that in FIG. 13, the steps are executed by control circuit 270, but at least one of or all of the steps may be executed by a control circuit of another processor, for instance, disposed outside AI processing device 200.

As described above, artificial intelligence processing device 200 according to the present disclosure includes: substrate 1, for instance; and multiply-accumulate operation circuit 215 that is provided on substrate 1, for instance, and performs a multiply-accumulate operation. Multiply-accumulate operation circuit 215 includes: first variable-resistance nonvolatile storage element 10 and second variable-resistance nonvolatile storage element 20 that hold, as conductance, a connection weight coefficient for use in calculating a product in the multiply-accumulate operation, first variable-resistance nonvolatile storage element 10 and second variable-resistance nonvolatile storage element 20 having different properties, and when successive applications of a voltage pulse with a same polarity and a same voltage are made, a proportion of an amount of change in the conductance caused by a second application of the voltage pulse relative to an amount of change in the conductance caused by a first application of the voltage pulse in first variable-resistance nonvolatile storage element 10 is less than a proportion of an amount of change in the conductance caused by a second application of the voltage pulse relative to an amount of change in the conductance caused by a first application of the voltage pulse in second variable-resistance nonvolatile storage element 20.

Accordingly, first variable-resistance nonvolatile storage element 10 having a property that the conductance greatly changes by the first application of a voltage pulse out of successive applications of the voltage pulse and an amount of change caused by subsequent applications of the voltage pulse is small can be used for setting a connection weight coefficient (initial setting), whereas second variable-resistance nonvolatile storage element 20 having a property that the conductance gradually changes by successive applications of the voltage pulse can be used for updating the connection weight coefficient (training). Thus, an artificial intelligence processing device that includes variable-resistance nonvolatile storage elements and can achieve both setting connection weight coefficients (initial setting) with high accuracy at the time of product shipment, for instance, and updating connection weight coefficients (training) with high efficiency after product shipment, for instance, can be embodied.

Artificial intelligence processing device 200 according to the present disclosure includes: substrate 1, for instance; and multiply-accumulate operation circuit 215 that is provided on substrate 1, for instance, and performs a multiply-accumulate operation. Multiply-accumulate operation circuit 215 includes a plurality of variable-resistance nonvolatile storage elements. The plurality of variable-resistance nonvolatile storage elements each include: first electrode 2, for instance; second electrode 4, for instance; and variable resistance layer 3 provided between first electrode 2, for instance, and second electrode 4, for instance. The plurality of variable-resistance nonvolatile storage elements hold, as conductance, a connection weight coefficient for use in calculating a product in the multiply-accumulate operation. The plurality of variable-resistance nonvolatile storage elements include first variable-resistance nonvolatile storage element 10 and second variable-resistance nonvolatile storage element 20 that have different properties. In first variable-resistance nonvolatile storage element 10, at least one of first electrode 1, for instance, or second electrode 4, for instance, is a noble metal electrode, and in second variable-resistance nonvolatile storage element 20, at least one of first electrode 1, for instance, or second electrode 4, for instance, is a non-noble metal electrode.

Accordingly, this acquires properties that when successive applications of a voltage pulse with the same polarity and the same voltage are made, a proportion of an amount of change in conductance caused by the second application of the voltage pulse relative to an amount of change in conductance caused by the first application of the voltage pulse in first variable-resistance nonvolatile storage element 10 is less than a proportion of an amount of change in conductance caused by the second application of the voltage pulse relative to an amount of change caused by the first application of the voltage pulse in second variable-resistance nonvolatile storage element 20. Thus, an artificial intelligence processing device that includes variable-resistance nonvolatile storage elements and can achieve both setting connection weight coefficients (initial setting) with high accuracy at the time of product shipment, for instance, and updating connection weight coefficients (training) with high efficiency after product shipment, for instance, can be embodied, by using first variable-resistance nonvolatile storage element 10 for setting a connection weight coefficient (initial setting) and second variable-resistance nonvolatile storage element 20 for updating a connection weight coefficient (training).

Note that specifically, the noble metal electrode includes at least one of Ir or Pt, and the non-noble metal electrode includes at least one of TiN or TaN.

Artificial intelligence processing device 200 according to the present disclosure includes: substrate 1, for instance; and multiply-accumulate operation circuit 215 that is provided on substrate 1, for instance, and performs a multiply-accumulate operation. Multiply-accumulate operation circuit 215 includes first variable-resistance nonvolatile storage element 10 and second variable-resistance nonvolatile storage element 20 that hold, as conductance, a connection weight coefficient for use in calculating a product in the multiply-accumulate operation, first variable-resistance nonvolatile storage element 10 and second variable-resistance nonvolatile storage element 20 having different properties. First variable-resistance nonvolatile storage element 10 has a retention property higher than a retention property of second variable-resistance nonvolatile storage element 20, and second variable-resistance nonvolatile storage element 20 has an endurance property higher than an endurance property of first variable-resistance nonvolatile storage element 10.

Accordingly, first variable-resistance nonvolatile storage element 10 having a higher retention property after writing is performed can be used for setting a connection weight coefficient (initial setting), and second variable-resistance nonvolatile storage element 20 having a high endurance property and a low degree of deterioration of the element due to writing can be used to update the connection weight coefficient (training). Thus, an artificial intelligence processing device that includes variable-resistance nonvolatile storage elements and can achieve both setting connection weight coefficients (initial setting) with high accuracy at the time of product shipment, for instance, and updating connection weight coefficients (training) with high efficiency after product shipment, for instance, can be embodied.

Here, multiply-accumulate operation circuit 215 obtains a sum total of a current flowing through first variable-resistance nonvolatile storage element 10 and a current flowing through second variable-resistance nonvolatile storage element 20, and outputs the sum total obtained, as one product in the multiply-accumulate operation. Accordingly, one connection weight coefficient can be obtained by using the conductance of first variable-resistance nonvolatile storage element 10 and the conductance of second variable-resistance nonvolatile storage element 20, and memory cells that include first variable-resistance nonvolatile storage elements 10 and second variable-resistance nonvolatile storage elements 20 can be caused to correspond to one neuron.

A plurality of wiring layers may be provided above substrate 1, for instance, and first variable-resistance nonvolatile storage element 10 and second variable-resistance nonvolatile storage element 20 may be provided between different pairs of wiring layers included in the plurality of wiring layers. Accordingly, different manufacturing processes can be used for first variable-resistance nonvolatile storage element 10 and second variable-resistance nonvolatile storage element 20.

A wiring layer may be provided above substrate 1, for instance, and first variable-resistance nonvolatile storage element 10 and second variable-resistance nonvolatile storage element 20 may be connected to each other via the wiring layer. Accordingly, first variable-resistance nonvolatile storage element 10 and second variable-resistance nonvolatile storage element 20 are connected by a common wiring layer, and the common wiring layer simplifies the structure.

In a view in a direction perpendicular to a plane of substrate 1, for instance, a center of first variable-resistance nonvolatile storage element 10 and a center of second variable-resistance nonvolatile storage element 20 may not coincide with each other. Accordingly, regions in a plan view for first variable resistance 10 and second variable-resistance nonvolatile storage element 20 can be distinguished, and first variable resistance 10 and second variable-resistance nonvolatile storage element 20 can be formed.

The conductance of first variable-resistance nonvolatile storage element 10 may be changed at least one of (i) when firmware is updated before or after shipping artificial intelligence processing device 200, (ii) when a learning model is updated, (iii) when regular maintenance is performed, or (iv) when the connection weight coefficient is insufficiently updated by changing the conductance of second variable-resistance nonvolatile storage element 20, and the conductance of second variable-resistance nonvolatile storage element 20 may be changed when the connection weight coefficient is updated to train artificial intelligence processing device 200 after being shipped. Accordingly, this can achieve both of setting connection weight coefficients (initial setting) with high accuracy at the time of product shipment, for instance, and updating connection weight coefficients (training) with high efficiency after product shipment, for instance.

At least one of transfer learning or reinforcement learning is applied to artificial intelligence processing device 200, the transfer learning and the reinforcement learning each being learning in which connection weight coefficient setting of an existing neural network is used. Artificial intelligence processing device 200 includes: a first neural network region in which the connection weight coefficient setting of the existing neural network is used as-is; and a second neural network region that is newly trained. The conductance of first variable-resistance nonvolatile storage element 10 is updated for the connection weight coefficient setting used in the first neural network region, and the conductance of second variable-resistance nonvolatile storage element 20 is updated for connection weight coefficient setting of the second neural network region. Accordingly, first variable-resistance nonvolatile storage element 10 having a higher retention property after writing is performed is used for setting a connection weight coefficient (initial setting), and second variable-resistance nonvolatile storage element 20 having a high endurance property and a low degree of deterioration of the element due to writing is used to update the connection weight coefficient (training). Thus, AI processing device 200 that makes use of properties of first variable-resistance nonvolatile storage element 10 and second variable-resistance nonvolatile storage element 20 can be embodied.

A training inference method for AI processing device 200 according to the present disclosure includes: determining (S30), in a case where the connection weight coefficient is to be changed, whether the case is a first case in which the connection weight coefficient is changed for initial setting or a second case in which the connection weight coefficient is changed in training; changing (S31 to S32) the conductance of first variable-resistance nonvolatile storage element 10 when the case is determined to be the first case as a result of the determining; changing (S35 to S39) the conductance of second variable-resistance nonvolatile storage element 20 when the case is determined to be the second case as a result of the determining; and making inference (reading out) by using, as one product in the multiply-accumulate operation, a sum total of a current flowing through first variable-resistance nonvolatile storage element 10 and a current flowing through second variable-resistance nonvolatile storage element 20, the sum total being output by multiply-accumulate operation circuit 215.

Accordingly, by determining a purpose, the conductance of only one of first variable-resistance nonvolatile storage element 10 or second variable-resistance nonvolatile storage element 20 is updated, setting connection weight coefficients (initial setting) with high accuracy at the time of product shipment, for instance, and updating connection weight coefficients (training) with high efficiency after product shipment, for instance, can be both achieved.

Here, the first case includes at least one of (i) a case where firmware is updated before or after shipping artificial intelligence processing device 200, (ii) a case where a learning model is updated, (iii) a case where regular maintenance is performed, or (iv) a case where the connection weight coefficient is insufficiently updated by changing the conductance of second variable-resistance nonvolatile storage element 20, and the second case includes a case where the connection weight coefficient is updated to train artificial intelligence processing device 200 after being shipped. Accordingly, a training inference method for AI processing device 200 that makes use of the properties of first variable-resistance nonvolatile storage element 10 and second variable-resistance nonvolatile storage element 20 can be realized.

The above has explained the AI processing device according to the present disclosure and the training inference method therefor, based on embodiments, but the present disclosure is not limited to such embodiments. The scope of the present disclosure also encompasses embodiments as a result of adding, to the embodiments, various modifications that may be conceived by those skilled in the art, and other embodiments obtained by combining some elements in the embodiments, as long as the resultant embodiments do not depart from the gist of the present disclosure.

For example, in the embodiments, first variable-resistance nonvolatile storage element 10 and second variable-resistance nonvolatile storage element 20 each include a variable resistance layer that includes a tantalum oxide. Yet, the material of the variable resistance layer is not limited to such a material, but the variable resistance layer may include an aluminum oxide or a transition metal oxide such as a hafnium oxide.

In the above embodiments, the variable resistance layers of first variable-resistance nonvolatile storage element 10 and second variable-resistance nonvolatile storage element 20 include stack structures each including a first tantalum oxide layer and a second tantalum oxide layer, but are not limited to such stack structures, and may each include a single layer such as a tantalum oxide layer.

In the above embodiments, one neuron includes one first variable-resistance nonvolatile storage element 10 and one second variable-resistance nonvolatile storage element 20, but may include two or more first variable-resistance nonvolatile storage elements 10 and two or more second variable-resistance nonvolatile storage elements 20 as long as at least one first variable-resistance nonvolatile storage element 10 and at least one second variable-resistance nonvolatile storage element 20 are included.

In the above embodiments, AI processing device 200 includes a neural network having a structure illustrated in FIG. 9A, but the structure is not limited thereto, and may be a neural network that includes a desired number of layers each including a desired number of neurons.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

An artificial intelligence processing device that includes variable-resistance nonvolatile storage elements according to the present disclosure can achieve both setting connection weight coefficients (initial setting) with high efficiency and accuracy at the time of product shipment, for instance, and updating connection weight coefficients (training) with high efficiency after product shipment, for instance, and is useful particularly as an edge AI processing device for IoT, for instance.

1. An artificial intelligence processing device comprising:
a substrate; and
a multiply-accumulate operation circuit that is provided on the substrate, and performs a multiply-accumulate operation,
wherein the multiply-accumulate operation circuit includes: a first variable-resistance nonvolatile storage element and a second variable-resistance nonvolatile storage element that hold, as conductance, a connection weight coefficient for use in calculating a product in the multiply-accumulate operation, the first variable-resistance nonvolatile storage element and the second variable-resistance nonvolatile storage element having different properties, and
when successive applications of a voltage pulse with a same polarity and a same voltage are made,
a proportion of an amount of change in the conductance caused by a second application of the voltage pulse relative to an amount of change in the conductance caused by a first application of the voltage pulse in the first variable-resistance nonvolatile storage element is less than a proportion of an amount of change in the conductance caused by a second application of the voltage pulse relative to an amount of change in the conductance caused by a first application of the voltage pulse in the second variable-resistance nonvolatile storage element.

2. An artificial intelligence processing device comprising:
a substrate; and
a multiply-accumulate operation circuit that is provided on the substrate, and performs a multiply-accumulate operation,
wherein the multiply-accumulate operation circuit includes a plurality of variable-resistance nonvolatile storage elements,
the plurality of variable-resistance nonvolatile storage elements each include:
a first electrode;
a second electrode; and
a variable resistance layer provided between the first electrode and the second electrode,
the plurality of variable-resistance nonvolatile storage elements hold, as conductance, a connection weight coefficient for use in calculating a product in the multiply-accumulate operation,
the plurality of variable-resistance nonvolatile storage elements include a first variable-resistance nonvolatile storage element and a second variable-resistance nonvolatile storage element that have different properties,
in the first variable-resistance nonvolatile storage element, at least one of the first electrode or the second electrode is a noble metal electrode, and
in the second variable-resistance nonvolatile storage element, at least one of the first electrode or the second electrode is a non-noble metal electrode.

3. The artificial intelligence processing device according to claim 2,
wherein the noble metal electrode includes at least one of Ir or Pt, and
the non-noble metal electrode includes at least one of TiN or TaN.

4. An artificial intelligence processing device comprising:
a substrate; and
a multiply-accumulate operation circuit that is provided on the substrate, and performs a multiply-accumulate operation,
wherein the multiply-accumulate operation circuit includes a first variable-resistance nonvolatile storage element and a second variable-resistance nonvolatile storage element that hold, as conductance, a connection weight coefficient for use in calculating a product in the multiply-accumulate operation, the first variable-resistance nonvolatile storage element and the second variable-resistance nonvolatile storage element having different properties,
the first variable-resistance nonvolatile storage element has a retention property higher than a retention property of the second variable-resistance nonvolatile storage element, and
the second variable-resistance nonvolatile storage element has an endurance property higher than an endurance property of the first variable-resistance nonvolatile storage element.

5. The artificial intelligence processing device according to claim 1,
wherein the multiply-accumulate operation circuit obtains a sum total of a current flowing through the first variable-resistance nonvolatile storage element and a current flowing through the second variable-resistance nonvolatile storage element, and outputs the sum total obtained, as one product in the multiply-accumulate operation.

6. The artificial intelligence processing device according to claim 1,
wherein a plurality of wiring layers are provided above the substrate, and
the first variable-resistance nonvolatile storage element and the second variable-resistance nonvolatile storage element are provided between different pairs of wiring layers included in the plurality of wiring layers.

7. The artificial intelligence processing device according to claim 1,
wherein a wiring layer is provided above the substrate, and
the first variable-resistance nonvolatile storage element and the second variable-resistance nonvolatile storage element are connected to each other via the wiring layer.

8. The artificial intelligence processing device according to claim 1,
wherein in a view in a direction perpendicular to a plane of the substrate, a center of the first variable-resistance nonvolatile storage element and a center of the second variable-resistance nonvolatile storage element do not coincide with each other.

9. The artificial intelligence processing device according to claim 1,
wherein the conductance of the first variable-resistance nonvolatile storage element is changed at least one of (i) when firmware is updated before or after shipping the artificial intelligence processing device, (ii) when a learning model is updated, (iii) when regular maintenance is performed, or (iv) when the connection weight coefficient is insufficiently updated by changing the conductance of the second variable-resistance nonvolatile storage element, and
the conductance of the second variable-resistance nonvolatile storage element is changed when the connection weight coefficient is updated to train the artificial intelligence processing device after being shipped.

10. The artificial intelligence processing device according to claim 1,
wherein the first variable-resistance nonvolatile storage element and the second variable-resistance nonvolatile storage element each include:
a first electrode;
a second electrode; and
a variable resistance layer provided between the first electrode and the second electrode,
in the first variable-resistance nonvolatile storage element, at least one of the first electrode or the second electrode is a noble metal electrode, and
in the second variable-resistance nonvolatile storage element, at least one of the first electrode or the second electrode is a non-noble metal electrode.

11. The artificial intelligence processing device according to claim 1,
wherein the first variable-resistance nonvolatile storage element has a retention property higher than a retention property of the second variable-resistance nonvolatile storage element, and
the second variable-resistance nonvolatile storage element has an endurance property higher than an endurance property of the first variable-resistance nonvolatile storage element.

12. The artificial intelligence processing device according to claim 1,
wherein at least one of transfer learning or reinforcement learning is applied to the artificial intelligence processing device,
the transfer learning and the reinforcement learning is learning in which connection weight coefficient setting of an existing neural network is used,
the artificial intelligence processing device includes:
a first neural network region; and
a second neural network region,
in the first neural network region, the connection weight coefficient setting of the existing neural network is used as-is;
the second neural network region is newly trained,
the conductance of the first variable-resistance nonvolatile storage element is updated for the connection weight coefficient setting used in the first neural network region, and
the conductance of the second variable-resistance nonvolatile storage element is updated for connection weight coefficient setting of the second neural network region.

13. A training inference method for the artificial intelligence processing device according to claim 1, the training inference method comprising:
determining, in a case where the connection weight coefficient is to be changed, whether the case is a first case in which the connection weight coefficient is changed for initial setting or a second case in which the connection weight coefficient is changed in training;
changing the conductance of the first variable-resistance nonvolatile storage element when the case is determined to be the first case as a result of the determining;
changing the conductance of the second variable-resistance nonvolatile storage element when the case is determined to be the second case as a result of the determining; and
making inference by using, as one product in the multiply-accumulate operation, a sum total of a current flowing through the first variable-resistance nonvolatile storage element and a current flowing through the second variable-resistance nonvolatile storage element, the sum total being output by the multiply-accumulate operation circuit.

14. The training inference method according to claim 13,
wherein the first case includes at least one of (i) a case where firmware is updated before or after shipping the artificial intelligence processing device, (ii) a case where a learning model is updated, (iii) a case where regular maintenance is performed, or (iv) a case where the connection weight coefficient is insufficiently updated by changing the conductance of the second variable-resistance nonvolatile storage element, and
the second case includes a case where the connection weight coefficient is updated to train the artificial intelligence processing device after being shipped.
